(19) United States
(12) Patent Application Publication
(10) Pub. No.: US 2019/0062148 A1
(43) Pub. Date: Feb. 28, 2019

(54) SENSOR

(71) Applicant: KABUSHIKI KAISHA TOSHIBA, Tokyo (JP)

(72) Inventors: Akiko YUZAWA, Kawasaki Kanagawa (JP); Yoshihiko FUJI, Kawasaki Kanagawa (JP); Michiko HARA, Yokohama Kanagawa (JP); Kenji OTSU, Yokohama Kanagawa (JP); Kazuaki OKAMOTO, Yokohama Kanagawa (JP); Shotaro BABA, Kawasaki Kanagawa (JP)

(73) Assignee: KABUSHIKI KAISHA TOSHIBA, Tokyo (JP)

(21) Appl. No.: 15/922,152

(22) Filed: Mar. 15, 2018

(30) Foreign Application Priority Data
Aug. 30, 2017 (JP) 2017-166016
Mar. 9, 2018 (JP) 2018-042661

(51) Int. Cl. B81B 3/00; H01L 41/12; H01L 41/06

(52) U.S. Cl. CPC B81B 3/0051; B81B 3/0091; H01L 41/125; B81B 2203/0353; B81B 2201/0257; B81B 2201/0264; H01L 41/06

(57) ABSTRACT

According to one embodiment, a sensor includes a film portion, and a first sensor portion. The film portion includes a first film including a plurality of holes. The film portion is deformable. The first sensor portion is fixed to a portion of the film portion. The first sensor portion includes a first magnetic layer, a second magnetic layer, and a first intermediate layer. The second magnetic layer is provided between the first film and the first magnetic layer. The first intermediate layer is provided between the first magnetic layer and the second magnetic layer. A direction from at least a portion of the plurality of holes toward the first sensor portion is aligned with a first direction. The first direction is from the first film toward the first sensor portion.

### CROSS-REFERENCE TO RELATED APPLICATIONS

This application is based upon and claims the benefit of priority from Japanese Patent Application No. 2017-166016, filed on Aug. 30, 2017, and Japanese Patent Application No. 2018-42661, filed on Mar. 9, 2018; the entire contents of which are incorporated herein by reference.

### FIELD

Embodiments described herein relate generally to a sensor.

### BACKGROUND

There is a sensor such as a pressure sensor or the like that converts pressure applied from the outside into an electrical signal. It is desirable to increase the sensing precision of the sensor.

### BRIEF DESCRIPTION OF THE DRAWINGS

FIG. 1A to FIG. 1D are schematic views illustrating a sensor according to an embodiment;

FIG. 2A and FIG. 2B are schematic cross-sectional views illustrating a portion of the film portion of the sensor according to the embodiment;

FIG. 3 is a schematic view illustrating the characteristics of the sensor according to the embodiment;

FIG. 4 is a schematic cross-sectional view illustrating a portion of another sensor according to the embodiment;

FIG. 5 is a schematic cross-sectional view illustrating a portion of another sensor according to the embodiment;

FIG. 6 is a schematic cross-sectional view illustrating a portion of another sensor according to the embodiment;

FIG. 7A to FIG. 7D are schematic cross-sectional views illustrating sensors according to the embodiment;

FIG. 8 is a schematic perspective view illustrating a portion of the sensor according to the embodiment;

FIG. 9 is a schematic perspective view illustrating a portion of another sensor according to the embodiment;

FIG. 10 is a schematic perspective view illustrating a portion of another sensor according to the embodiment;

FIG. 11 is a schematic perspective view illustrating a portion of another sensor according to the embodiment;

FIG. 12 is a schematic perspective view illustrating a portion of another sensor according to the embodiment;

FIG. 13 is a schematic perspective view illustrating a portion of another sensor according to the embodiment;

FIG. 14 is a schematic perspective view illustrating a portion of another sensor according to the embodiment;

FIG. 15 is a schematic view illustrating the electronic device according to the second embodiment;

FIG. 16A and FIG. 16B are schematic cross-sectional views illustrating the electronic device according to the second embodiment;

FIG. 17A and FIG. 17B are schematic views illustrating another electronic device according to the second embodiment;

FIG. 18 is a schematic view illustrating another electronic device according to the second embodiment;

FIG. 19 is schematic cross-sectional views illustrating a portion of another sensor according to the embodiment;

FIG. 20 is schematic cross-sectional views illustrating a portion of another sensor according to the embodiment;

FIG. 21 is schematic cross-sectional views illustrating a portion of another sensor according to the embodiment;

FIG. 22 is schematic cross-sectional views illustrating a portion of another sensor according to the embodiment;

FIG. 23 is schematic cross-sectional views illustrating a portion of another sensor according to the embodiment;

FIG. 24 is schematic cross-sectional views illustrating a portion of another sensor according to the embodiment;

FIG. 25 is schematic cross-sectional views illustrating a portion of another sensor according to the embodiment;

FIG. 26 is schematic cross-sectional views illustrating a portion of another sensor according to the embodiment;

FIG. 27 is schematic cross-sectional views illustrating a portion of another sensor according to the embodiment;

FIG. 28 is schematic cross-sectional views illustrating a portion of another sensor according to the embodiment;

FIGS. 29A and 29B are schematic cross-sectional views illustrating a manufacturing method the sensor according to the embodiment;

FIG. 30 is schematic cross-sectional views illustrating a portion of another sensor according to the embodiment;

FIGS. 31A and 31B are schematic cross-sectional views illustrating a manufacturing method the sensor according to the embodiment;

FIG. 32 is schematic cross-sectional views illustrating a portion of another sensor according to the embodiment; and

FIGS. 33A and 33B are schematic cross-sectional views illustrating a manufacturing method the sensor according to the embodiment.

### DETAILED DESCRIPTION

According to one embodiment, a sensor includes a film portion, and a first sensor portion. The film portion includes a first film including a plurality of holes. The film portion is deformable. The first sensor portion is fixed to a portion of the film portion. The first sensor portion includes a first magnetic layer, a second magnetic layer, and a first intermediate layer. The second magnetic layer is provided between the first film and the first magnetic layer. The first intermediate layer is provided between the first magnetic layer and the second magnetic layer. A direction from at least a portion of the plurality of holes toward the first sensor portion is aligned with a first direction. The first direction is from the first film toward the first sensor portion.

According to one embodiment, a sensor includes a film portion, and a first sensor portion. The film portion includes a first film including a metal compound portion and a carbon-including portion. The film portion is deformable. The first sensor portion is fixed to a portion of the film portion. The first sensor portion includes a first magnetic layer, a second magnetic layer, and a first intermediate layer. The second magnetic layer is provided between the first film and the first magnetic layer. The first intermediate layer is provided between the first magnetic layer and the second magnetic layer. A direction from at least a portion of the metal compound portion toward at least a portion of the carbon-including portion crosses a first direction from the first film toward the first sensor portion.

Embodiments will now be described with reference to the drawings.

The drawings are schematic or conceptual; and the relationships between the thicknesses and widths of portions, the proportions of sizes between portions, etc., are not necessarily the same as the actual values thereof. There are also cases where the dimensions and/or the proportions are illustrated differently between the drawings, even in the case where the same portion is illustrated.

In this specification and each drawing, components similar to ones described in reference to an antecedent drawing are marked with the same reference numerals; and a detailed description is omitted as appropriate.

### First Embodiment

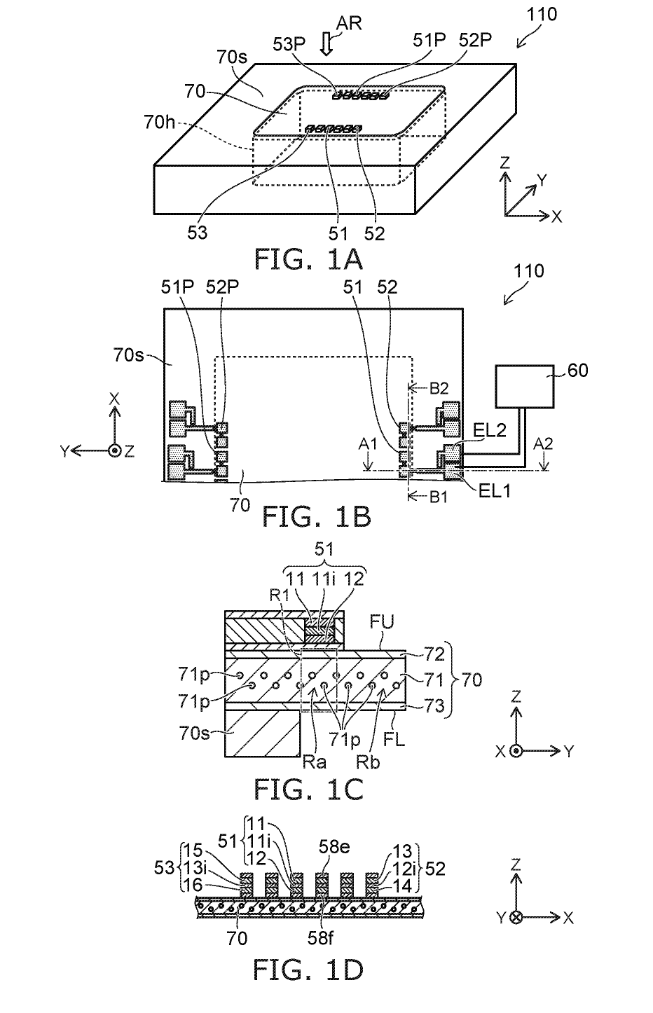

FIG. 1A to FIG. 1D are schematic views illustrating a sensor according to an embodiment.

FIG. 1A is a perspective view. FIG. 1B is a plan view showing a portion of the sensor when viewed along arrow AR of FIG. 1A. FIG. 1C is a line A1-A2 cross-sectional view of FIG. 1B. FIG. 1D is a line B1-B2 cross-sectional view of FIG. 1B.

As shown in FIG. 1A and FIG. 1B, the sensor 110 according to the embodiment includes a film portion 70 and a first sensor portion 51. The sensor 110 is, for example, a pressure sensor.

The film portion 70 is deformable. For example, the film portion 70 is supported by a supporter 70s. For example, a recess 70h is formed in a portion of the substrate used to form the film portion 70 and the supporter 70s. The thin portion of the substrate is used to form the film portion 70. The thick portion of the substrate is used to form the supporter 70s. In the example, the supporter 70s is connected to the outer edge of the film portion 70. The planar configuration of the film portion 70 is, for example, substantially a quadrilateral (including a rectangle, etc.), a circle (including a flattened circle), etc. The deformable film portion recited above may have a free end.

As shown in FIG. 1C, the film portion 70 includes a first film 71.

A direction (a first direction) that connects the first film 71 and the first sensor portion 51 is taken as a Z-axis direction. For example, the direction of the shortest line connecting the first film 71 and the first sensor portion 51 corresponds to the first direction.

One axis perpendicular to the Z-axis direction is taken as an X-axis direction. A direction perpendicular to the Z-axis direction and the X-axis direction is taken as a Y-axis direction.

In the example, the film portion 70 further includes a second film 72 and a third film 73. At least one of the second film 72 or the third film 73 may be omitted. The second film 72 is provided between the third film 73 and the first sensor portion 51. The first film 71 is provided between the second film 72 and the third film 73. The direction from the first film 71 toward the second film 72 is aligned with the Z-axis direction. The direction from the third film 73 toward the first film 71 is aligned with the Z-axis direction. The position in the Z-axis direction of the first film 71 is between the position in the Z-axis direction of the second film 72 and the position in the Z-axis direction of the third film 73.

For example, at least a portion of an upper surface FU of the film portion 70 (in the example, the upper surface of the second film 72) contacts a gas or a liquid. For example, at least a portion of a lower surface FL of the film portion 70 (in the example, the lower surface of the third film 73) contacts a gas or a liquid.

The first sensor portion 51 is provided at the film portion 70. For example, the first sensor portion 51 is fixed on the surface of a portion of the film portion 70. The front and back (the top and bottom) of the surface are arbitrary.

As shown in FIG. 1D, the first sensor portion 51 includes a first magnetic layer 11, a second magnetic layer 12, and a first intermediate layer 11i. The second magnetic layer 12 is provided between the first film 71 and the first magnetic layer 11. The first intermediate layer 11i is provided between the first magnetic layer 11 and the second magnetic layer 12. In the example, the direction from the second magnetic layer 12 toward the first magnetic layer 11 corresponds to the Z-axis direction.

Multiple sensor portions (e.g., a second sensor portion 52, a third sensor portion 53, a sensor portion 51P, a sensor portion 52P, a sensor portion 53P, etc.) are provided in the example. In the example, at least a portion of the second sensor portion 52 overlaps at least a portion of the first sensor portion 51 along the X-axis direction. The first sensor portion 51 is provided between the second sensor portion 52 and the third sensor portion 53. At least a portion of the sensor portion 51P overlaps at least a portion of the first sensor portion 51 along the Y-axis direction. At least a portion of the sensor portion 52P overlaps at least a portion of the second sensor portion 52 along the Y-axis direction. At least a portion of the sensor portion 53P overlaps at least a portion of the third sensor portion 53 along the Y-axis direction.

The second sensor portion 52 includes a third magnetic layer 13, a fourth magnetic layer 14, and a second intermediate layer 12i. The fourth magnetic layer 14 is provided between the first film 71 and the third magnetic layer 13. The second intermediate layer 12i is provided between the third magnetic layer 13 and the fourth magnetic layer 14.

The third sensor portion 53 includes a fifth magnetic layer 15, a sixth magnetic layer 16, and a third intermediate layer 13i. The sixth magnetic layer 16 is provided between the first film 71 and the fifth magnetic layer 15. The third intermediate layer 13i is provided between the fifth magnetic layer 15 and the sixth magnetic layer 16.

The configurations of the sensor portions 51P to 53P are similar to those of the first to third sensor portions 51 to 53.

As shown in FIG. 1D, the magnetic layer recited above is provided between a first sensor conductive layer 58e and the film portion 70. A second sensor conductive layer 58f is provided between the film portion 70 and the magnetic layer recited above.

The first sensor conductive layer 58e that is electrically connected to the first sensor portion 51 is electrically connected to a first sensor electrode EL1. The second sensor conductive layer 58f that is electrically connected to the first sensor portion 51 is electrically connected to a second sensor electrode EL2.

The magnetization of at least one of the first magnetic layer 11 or the second magnetic layer 12 changes according to the deformation of the film portion 70. The angle between the magnetization of the first magnetic layer 11 and the magnetization of the second magnetic layer 12 changes according to the deformation of the film portion 70. The electrical resistance between the first magnetic layer 11 and the second magnetic layer 12 (the electrical resistance of the first sensor portion 51) changes due to the change of this angle. For example, the pressure that is applied to the film portion 70 can be sensed by sensing the change of the electrical resistance between the first sensor electrode EL1 and the second sensor electrode EL2. The pressure is, for example, a sound wave, etc.

In the embodiment, the state of being electrically connected includes not only the state in which multiple conductors are in direct contact, but also the case where the multiple conductors are connected via another conductor. The state of being electrically connected includes the case where multiple conductors are connected via an element having a function such as switching, amplification, etc. For example, at least one of a switch element or an amplifier element may be inserted into at least one of a current path between the first sensor electrode EL1 and the first magnetic layer 11 or a current path between the second sensor electrode EL2 and the second magnetic layer 12.

For example, the first magnetic layer 11 is a free magnetic layer; and the second magnetic layer 12 is a magnetization reference layer. For example, the first magnetic layer 11 may be a magnetization reference layer; and the second magnetic layer 12 may be a free magnetic layer. Both the first magnetic layer 11 and the second magnetic layer 12 may be free magnetic layers. The description relating to the first sensor portion 51 recited above is applicable also to the other sensor portions (the second sensor portion 52, the third sensor portion 53, the sensor portion 51P, the sensor portion 52P, the sensor portion 53P, etc.).

As shown in FIG. 1A and FIG. 1B, the sensor 110 may further include a controller 60. The controller 60 is electrically connected to the sensor portions (the first sensor portion 51, etc.). The controller 60 is electrically connected to the first sensor electrode EL1 and the second sensor electrode EL2. The controller 60 includes a circuit sensing the electrical resistances of the sensor portions.

The first film 71 includes multiple holes 71p. At least a portion of the multiple holes 71p is positioned in a first region Ra of the first film 71 overlapping the sensor portion in the Z-axis direction. In other words, the direction from at least a portion of the multiple holes 71p toward the first sensor portion 51 is aligned with the Z-axis direction. The first film 71 is, for example, a porous film. In the example, a portion of the multiple holes 71p is provided also in a second region Rb of the first film 71 that does not overlap the sensor portion in the Z-axis direction. For example, the multiple holes 71p are distributed in the entire first film 71.

For example, the change of the electrical resistance with respect to the strain (the stress) is large for the sensor portions (the first sensor portion 51, etc.) that use the magnetic layers. In other words, the sensitivity is high. However, there are cases where the range of the strain (the stress) obtained with high sensitivity is relatively narrow.

Conversely, in the embodiment, the density of the first film 71 is adjusted by the multiple holes 71p. Thereby, the resonant frequency of the film portion 70 changes. Thereby, the width of the sensible range of the stress (e.g., the sound wave or the like) to be sensed can be adjusted. For example, the stress in the desired range can be sensed with high precision.

According to the embodiment, a sensor can be provided in which the sensing precision can be increased.

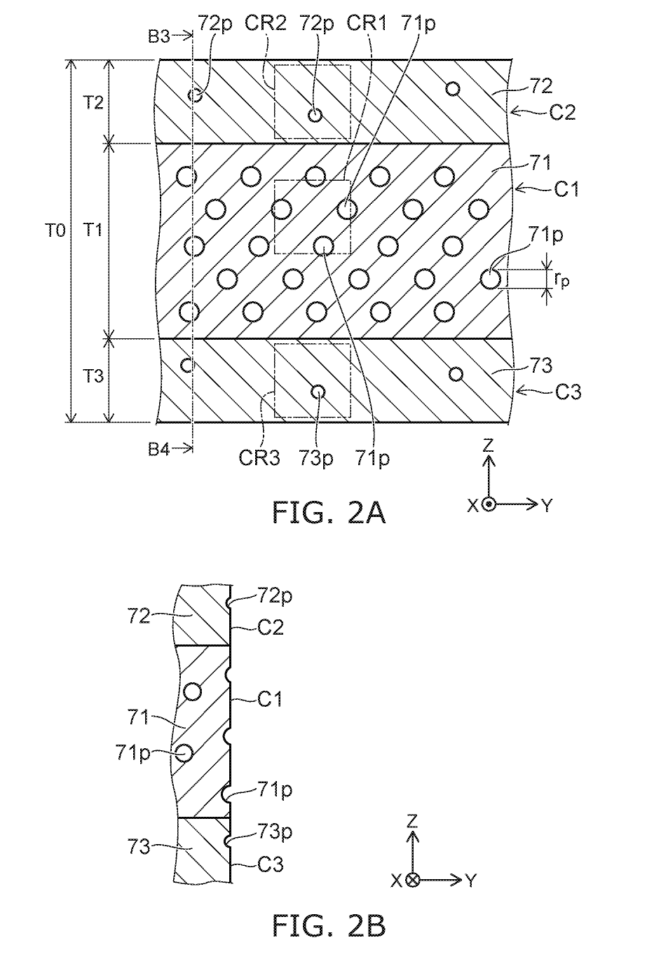

FIG. 2A and FIG. 2B are schematic cross-sectional views illustrating a portion of the film portion of the sensor according to the embodiment.

FIG. 2A is an enlarged view of a region R1 of the film portion 70 shown in FIG. 1C. The region R1 is a portion arranged with the first sensor portion 51 in the Z-axis direction. FIG. 2B is a line B3-B4 cross-sectional view of FIG. 2A.

As described above, the first film 71 is, for example, a porous film. The first film 71 includes, for example, at least one selected from the group consisting of an oxide of a first element, a phosphate of the first element, and an oxynitride of the first element. The first element includes, for example, at least one selected from the group consisting of silicon, aluminum, calcium, boron, tungsten, and titanium.

For example, the first film 71 includes at least one selected from the group consisting of silicon oxide, aluminum oxide, titanium oxide, aluminum silicate, silicon oxynitride, aluminophosphate, aluminosilicate, and aluminum phosphate. In such a case, for example, the first film 71 is formed using a sol-gel method and/or vapor deposition. For example, the first film 71 is formed by performing heat treatment of a film including a surfactant, silicon, etc. The first film 71 may include zeolite.

The first film 71 may include, for example, an organic substance. For example, the first film 71 includes a surfactant. For example, the first film 71 includes at least one of amino acid or deoxyribonucleic acid. For example, the first film 71 includes at least one selected from the group consisting of a hydroxy group, a carbonyl group, a carboxy group, an amine, an imine, an ester bond, and an ether bond in the molecular structure.

The average of diameters rp (equivalent circular diameters) of the holes 71p in a cross section (a first cross section C1) of the first film 71 is, for example, not less than 0.2 nanometers (nm) and not more than 1000 nm. A portion of the multiple holes 71p may communicate with each other. The first film 71 may have, for example, a mesh configuration. The multiple holes 71p are observed using a transmission electron microscope (TEM), a scanning electron microscope (SEM), etc., in any cross section of the first film 71.

For example, a thickness T1 along the Z-axis direction of the first film 71 is not less than 0.3 times and not more than 0.9 times a thickness T0 along the Z-axis direction of the film portion 70. The thickness T1 is, for example, not less than 50 nm and not more than 10 micrometers (μm).

The second film 72 includes, for example, at least one selected from the group consisting of silicon, silicon oxide, aluminum oxide, silicon nitride, aluminum silicate, and silicon oxynitride. The third film includes, for example, at least one selected from the group consisting of silicon, silicon oxide, aluminum oxide, silicon nitride, aluminum silicate, and silicon oxynitride.

In the example shown in FIG. 2A, the second film 72 includes multiple holes 72p; and the third film 73 includes multiple holes 73p. In one example, the second film 72 substantially does not include a hole. In one example, the third film 73 substantially does not include a hole.

The density (grams/cubic centimeter (g/cm³)) of the first film 71 is lower than the density of the second film and lower than the density of the third film. For example, the density of the first film 71 is not less than 0.9 g/cm³ and not more than 20.0 g/cm³.

The density of the multiple holes 71p inside the first film 71 is lower than the density of the multiple holes 72p inside the second film 72 and lower than the density of the multiple holes 73p inside the third film 73. The density of the multiple holes inside the film is the number of holes (holes/cm³) inside a film of unit volume.

For example, the density of the holes inside the film corresponds to the number of multiple holes per unit surface area (holes/cm²) at any cross section of the film.

For example, any cross section (the first cross section C1) of the first film 71 includes a first cross-sectional region CR1. For example, the cross section (a second cross section C2) of the second film 72 includes a second cross-sectional region CR2. For example, the cross section (a third cross section C3) of the third film 73 includes a third cross-sectional region CR3. The surface area of the first cross-sectional region CR1 is the same as the surface area of the second cross-sectional region CR2 and the same as the surface area of the third cross-sectional region CR3. In such a case, for example, the number of the multiple holes 71p included in the first cross-sectional region CR1 is greater than the number of the multiple holes 72p included in the second cross-sectional region CR2 and greater than the number of the multiple holes 73p included in the third cross-sectional region CR3.

The porosity of the first film 71 is higher than the porosity of the second film 72 and higher than the porosity of the third film 73. In other words, the proportion of the volume of the multiple holes 71p to the volume of the first film 71 is higher than the proportion of the volume of the multiple holes 72p to the volume of the second film 72 and higher than the proportion of the multiple holes 73p to the volume of the third film 73. The porosity of the first film is, for example, not less than 30% and not more than 85%. The porosity is determined from small-angle X-ray scattering, X-ray reflectometry, adsorption, etc. The porosity also can be determined using a scanning probe microscope, a scanning electron microscope, etc.

For example, the porosity corresponds to the surface area of the multiple holes per unit surface area in any cross section of the film.

For example, the proportion of the surface area of the multiple holes 71p included in the first cross-sectional region CR1 to the surface area of the first cross-sectional region CR1 is higher than the proportion of the surface area of the multiple holes 72p included in the second cross-sectional region CR2 to the surface area of the second cross-sectional region CR2. For example, the proportion of the surface area of the multiple holes 71p included in the first cross-sectional region CR1 to the surface area of the first cross-sectional region CR1 is higher than the proportion of the surface area of the multiple holes 73p included in the third cross-sectional region CR3 to the surface area of the third cross-sectional region CR3.

For example, an unevenness may occur in any cross section of the film due to the holes appearing at the surface. In such a case, as shown in FIG. 2B, the surface roughness of the first cross section Cl of the first film 71 is rougher than the surface roughness of the second cross section C2 of the second film 72 and rougher than the surface roughness of the third cross section C3 of the third film 73. For example, the surface roughness is the arithmetic average roughness Ra (JIS B 0601).

As shown in FIG. 2A, for example, the thickness T1 along the Z-axis direction of the first film 71 is thicker than a thickness T2 along the Z-axis direction of the second film 72. For example, the thickness T1 along the Z-axis direction of the first film 71 is thicker than a thickness T3 along the Z-axis direction of the third film 73.

For example, the thickness T1 is not less than 1.5 times and not more than 200 times the thickness T2. For example, the thickness T1 is not less than 1.5 times and not more than 200 times the thickness T3.

An example of characteristics of the sensor will now be described.

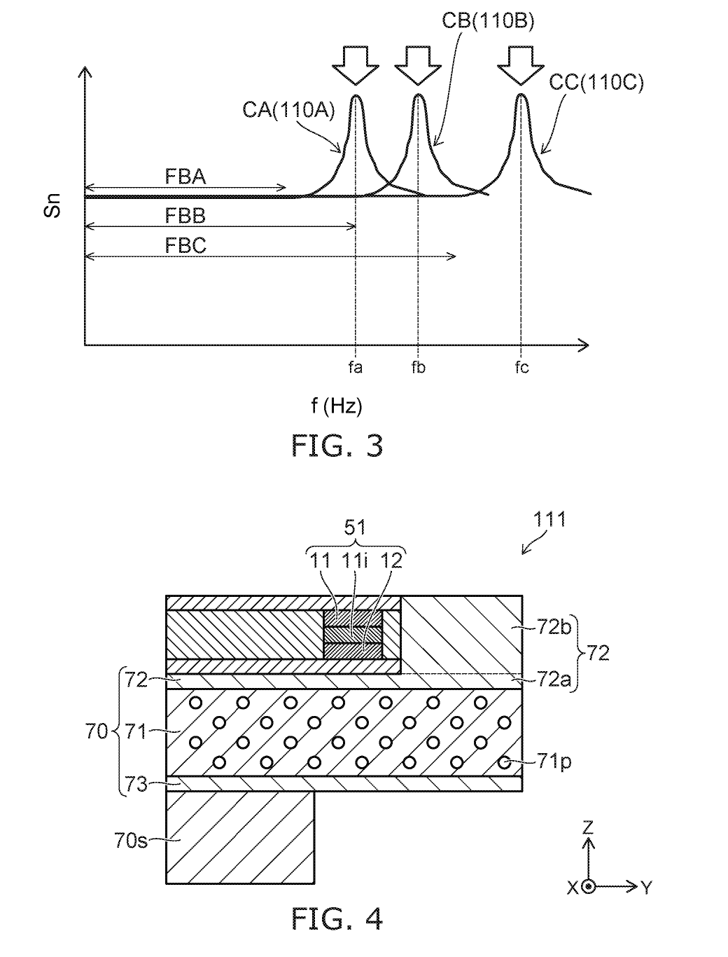

FIG. 3 is a schematic view illustrating the characteristics of the sensor according to the embodiment.

The horizontal axis of FIG. 3 is a frequency f (Hz); and the vertical axis of FIG. 3 is a sensitivity Sn of the sensor. The sensitivity Sn corresponds to the magnitude (the strain slope dϵ/dP) of a strain ϵ generated in the film portion 70 by a pressure P applied to the film portion 70.

FIG. 3 shows a characteristic CA of a sensor 110A, a characteristic CB of a sensor 110B, and a characteristic CC of a sensor 110C. The sensor 110A, the sensor 110B, and the sensor 110C each are sensors similar to the sensor 110 described above.

The porosity of the first film 71 of the sensor 110A is lower than the porosity of the first film 71 of the sensor 110B. In other words, the density of the first film 71 of the sensor 110A is higher than the density of the first film 71 of the sensor 110B.

The porosity of the first film 71 of the sensor 110B is lower than the porosity of the first film 71 of the sensor 110C. In other words, the density of the first film 71 of the sensor 110B is higher than the density of the first film 71 of the sensor 110C.

In such a case, a resonant frequency fb of the film portion 70 of the sensor 110B is higher than a resonant frequency fa of the film portion 70 of the sensor 110A. A resonant frequency fc of the film portion 70 of the sensor 110C is higher than the resonant frequency fb of the film portion 70 of the sensor 110B. The resonant frequency of the film portion 70 can be adjusted by the density of the first film 71. The sensing precision of the sensor can be increased by changing the resonant frequency to match the sensing object.

For example, the case is considered where a frequency band that is lower than the resonant frequency of the film portion 70 is used in the sensing. In other words, a relatively flat band of the frequency characteristic of the sensitivity is utilized. In such a case, a band FBC of the frequency sensed by the sensor 110C is wider than a band FBB of the frequency sensed by the sensor 110B. The band FBB is wider than a band FBA of the frequency sensed by the sensor 110A. Thus, the band of the frequency of the sensing object can be enlarged by setting the resonant frequency of the film portion to be high. There is a method of a reference example in which the resonant frequency is set to be high by changing the tensile stress and/or the surface area of the film portion 70. However, the sensitivity decreases in the method of the reference example. Conversely, in the embodiment, for example, the sensitivity in the band FBA, the sensitivity in the band FBB, and the sensitivity in the band FBC are equal to each other. According to the embodiment, the decrease of the sensitivity can be suppressed.

In the sensor 110 according to the embodiment, the primary resonant frequency of the film portion 70 is, for example, not less than 25 kHz and not more than 200 kHz. In the sensor 110, for example, stable sensing is possible in any band from the audible sound band to the ultrasonic region. According to the embodiment, for example, an ultrasonic sensor for a wide bandwidth having a substantially flat frequency characteristic can be provided.

In the case where the film portion includes a porous film, the sound wave may pass through the film portion and may be absorbed by the film portion. Conversely, the transmission and/or the absorption of the sound wave is suppressed by the second film 72 and the third film 73. Thereby, the decrease of the sensitivity can be suppressed further.

For example, the adsorption of substances inside a gas to the multiple holes 71p of the first film 71 can be suppressed by the second film 72 and the third film 73.

For example, when manufacturing the sensor 110, the first film 71 can be protected from process damage by the second film 72 and the third film 73.

FIG. 4 is a schematic cross-sectional view illustrating a portion of another sensor according to the embodiment.

FIG. 4 corresponds to the cross-sectional view shown in FIG. 1C. In the sensor 111 as shown in FIG. 4, the second film 72 includes a film region 72a and a film region 72b. Otherwise, the sensor 111 is similar to the sensor 110 described above.

The position in the Z-axis direction of the film region 72a is between the position in the Z-axis direction of the first sensor portion 51 and the position in the Z-axis direction of the first film 71. The film region 72b is arranged in the Y-axis direction with the first sensor portion 51. Thus, a portion of the first sensor portion 51 may be provided to be buried in the second film 72.

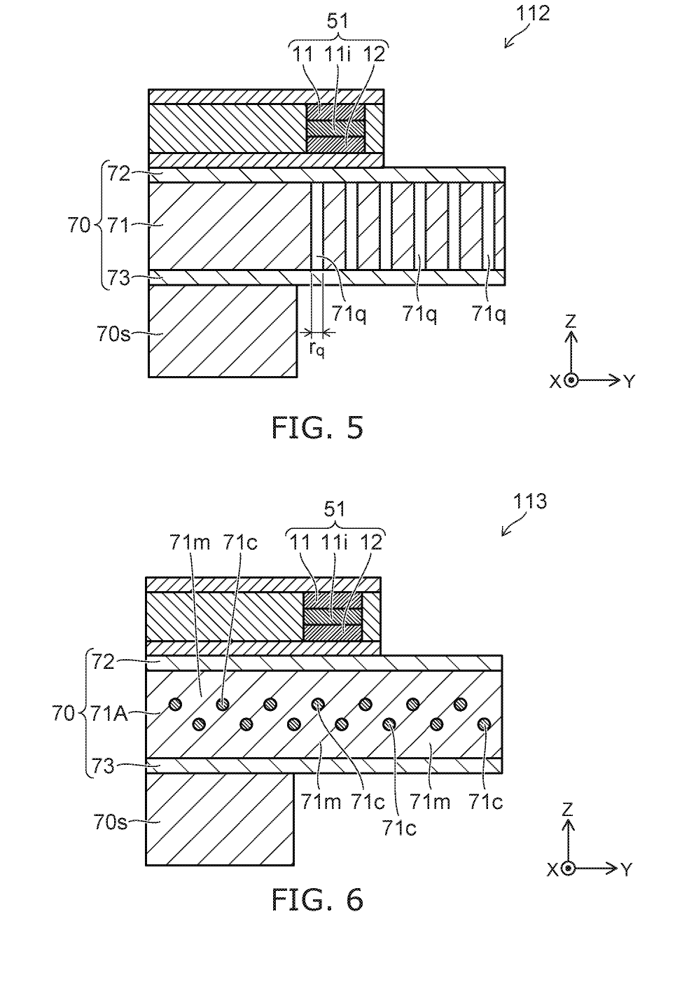

FIG. 5 is a schematic cross-sectional view illustrating a portion of another sensor according to the embodiment.

FIG. 5 corresponds to the cross-sectional view shown in FIG. 1C. In the sensor 112 according to the embodiment shown in FIG. 5, the first film 71 includes multiple holes 71q. The direction from at least a portion of the multiple holes 71q toward the first sensor portion 51 is aligned with the Z-axis direction. For example, the multiple holes 71q may be distributed in the entire first film 71. The multiple holes 71q may not be provided in a region of the first film 71 overlapping the supporter 70s in the Z-axis direction.

Each of the multiple holes 71q extends in the Z-axis direction. For example, each of the multiple holes 71q pierces the first film 71.

The first film 71 includes, for example, at least one selected from the group consisting of silicon, silicon oxide, aluminum oxide, silicon nitride, and carbon. In the example, the first film 71 may not be a porous film. For example, the multiple holes 71q can be formed by patterning using lithography and/or etching. Diameters rq (the lengths along the Y-axis direction) of the holes 71q are, for example, not less than 10 nm and not more than 10 μm.

FIG. 6 is a schematic cross-sectional view illustrating a portion of another sensor according to the embodiment.

FIG. 6 corresponds to the cross-sectional view shown in FIG. 1C. In the sensor 113 according to the embodiment shown in FIG. 6, the film portion 70 includes a first film 71A instead of the first film 71 described above. Otherwise, the sensor 113 is similar to the sensor 110.

The first film 71A includes a metal compound portion 71m and a carbon-including portion 71c. In the example, the first film 71A is a film in which the metal compound portion 71m and the carbon-including portion 71c are mixed. For example, the metal compound portion 71m is provided at the periphery of the carbon-including portion 71c and contacts the carbon-including portion 71c.

The direction from at least a portion of the metal compound portion 71m toward at least a portion of the carbon-including portion 71c crosses the Z-axis direction. For example, a portion of the metal compound portion 71m is arranged in the X-axis direction and the Y-axis direction with a portion of the carbon-including portion 71c. For example, a portion of the metal compound portion 71m is arranged in the Z-axis direction with another portion of the carbon-including portion 71c. For example, the metal compound portion 71m and the carbon-including portion 71c are distributed in the entire first film 71A.

The metal compound portion 71m includes at least one selected from the group consisting of an oxide, a nitride, and an oxynitride.

The oxide included in the metal compound portion 71m includes an oxide of at least one selected from the group consisting of silicon, aluminum, titanium, and tungsten.

The nitride included in the metal compound portion 71m includes a nitride of at least one selected from the group consisting of silicon, aluminum, titanium, and tungsten.

The oxynitride included in the metal compound portion 71m includes an oxynitride of at least one selected from the group consisting of silicon, aluminum, titanium, and tungsten.

The carbon-including portion 71c includes at least one selected from the group consisting of a hydroxy group, a carbonyl group, a carboxy group, an ether bond, an ester bond, an amine, and an imine.

The density of the metal compound portion 71m is different from the density of the carbon-including portion 71c. For example, much of the material having the low density is included in the first film 71A. Thereby, the resonant frequency of the film portion 70 can be set to be high. The band of the frequency of the sensing object can be enlarged.

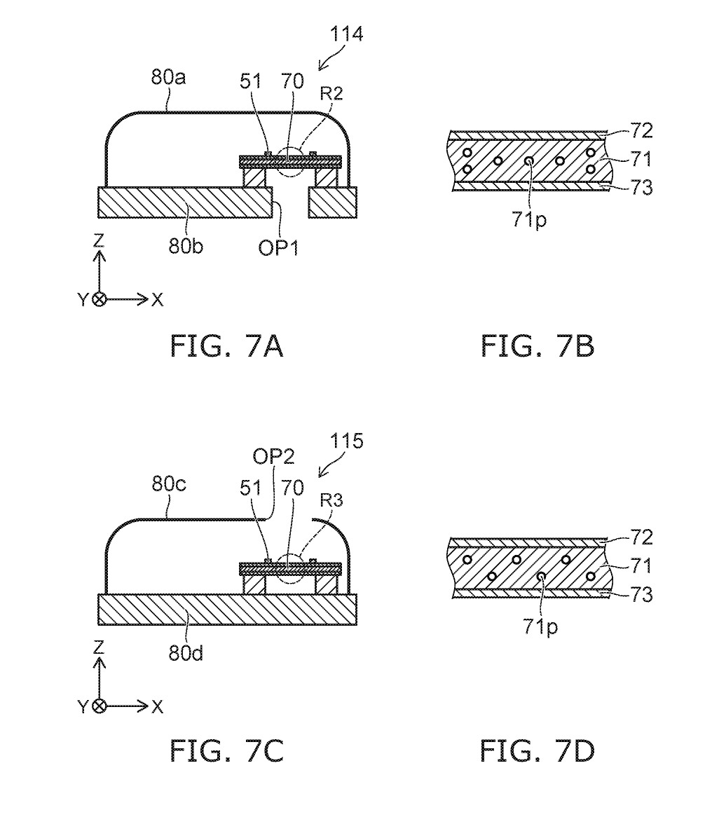

FIG. 7A to FIG. 7D are schematic cross-sectional views illustrating sensors according to the embodiment.

As shown in FIG. 7A, a sensor 114 includes a cover 80a (a first member) and a substrate 80b (a second member). The substrate 80b is, for example, a printed circuit board and includes a circuit such as an amplifier, etc. The sensor 110 described above (the first sensor portion 51 and the film portion 70) is provided between the cover 80a and the substrate 80b. The substrate 80b has an opening OP1. The sound wave reaches the film portion 70 via the opening OP1.

FIG. 7B is an enlarged view of a region R2 shown in FIG. 7A. As shown in FIG. 7A and FIG. 7B, at least a portion of the third film 73 is positioned between the opening OP1 and at least a portion of the first film 71. Thereby, the transmission of the sound wave through the first film 71 having the multiple holes 71p, etc., can be suppressed.

As shown in FIG. 7C, a sensor 115 includes a cover 80c (the second member) and a substrate 80d (the first member). The sensor 110 is provided between the cover 80c and the substrate 80d. The cover 80c has an opening OP2. The sound wave reaches the film portion 70 via the opening OP2. FIG. 7D is an enlarged view of a region R3 shown in FIG. 7C. At least a portion of the second film 72 is positioned between the opening OP2 and at least a portion of the first film 71. Thereby, the transmission of the sound wave through the first film 71, etc., can be suppressed.

Examples of sensor portions used in the embodiment will now be described. In the following description, the notation “material A/material B” indicates a state in which a layer of the material B is provided on a layer of the material A.

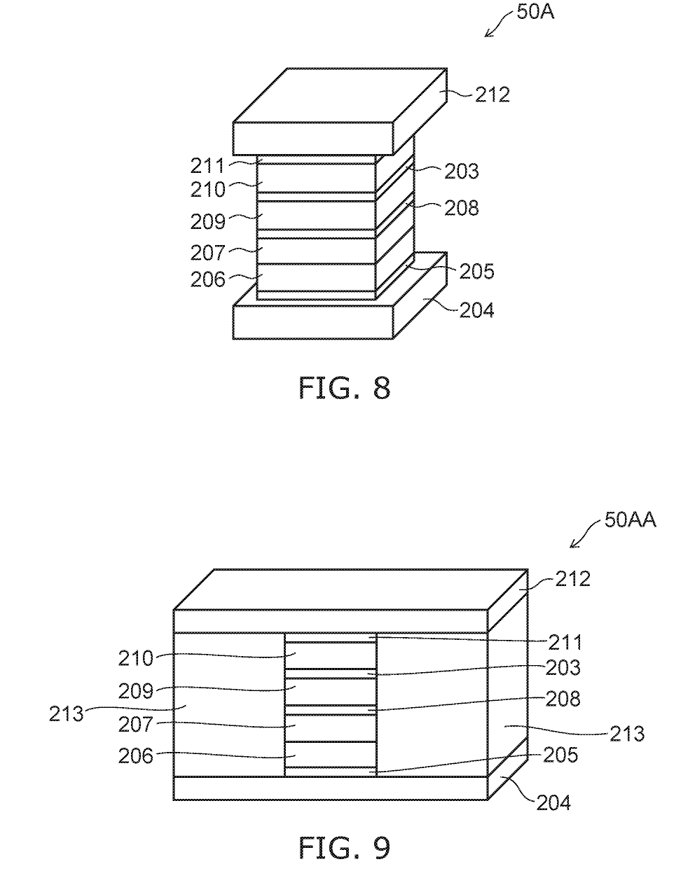

FIG. 8 is a schematic perspective view illustrating a portion of the sensor according to the embodiment.

In the sensor portion 50A as shown in FIG. 8, a lower electrode 204, a foundation layer 205, a pinning layer 206, a second magnetization reference layer 207, a magnetic coupling layer 208, a first magnetization reference layer 209, an intermediate layer 203, a free magnetic layer 210, a capping layer 211, and an upper electrode 212 are arranged in this order. The sensor portion 50A is, for example, a bottom spin-valve type. The magnetization reference layer is, for example, a fixed magnetic layer.

The foundation layer 205 includes, for example, a stacked film of tantalum and ruthenium (Ta/Ru). The thickness (the length in the Z-axis direction) of the Ta layer is, for example, 3 nanometers (nm). The thickness of the Ru layer is, for example, 2 nm. The pinning layer 206 includes, for example, an IrMn-layer having a thickness of 7 nm. The second magnetization reference layer 207 includes, for example, a Co₇₅Fe₂₅ layer having a thickness of 2.5 nm. The magnetic coupling layer 208 includes, for example, a Ru layer having a thickness of 0.9 nm. The first magnetization reference layer 209 includes, for example, a Co₄₀Fe₄₀B₂₀ layer having a thickness of 3 nm. The intermediate layer 203 includes, for example, a MgO layer having a thickness of 1.6 nm. The free magnetic layer 210 includes, for example, Co₄₀Fe₄₀B₂₀ having a thickness of 4 nm. The capping layer 211 includes, for example, Ta/Ru. The thickness of the Ta layer is, for example, 1 nm. The thickness of the Ru layer is, for example, 5 nm.

The lower electrode 204 and the upper electrode 212 include, for example, at least one selected from the group consisting of aluminum (Al), an aluminum copper alloy (Al—Cu), copper (Cu), silver (Ag), and gold (Au). By using such a material having a relatively small electrical resistance as the lower electrode 204 and the upper electrode 212, the current can be caused to flow efficiently in the sensor portion 50A. The lower electrode 204 and the upper electrode 212 include nonmagnetic materials.

The lower electrode 204 and the upper electrode 212 may include, for example, a foundation layer (not illustrated) for the lower electrode 204 and the upper electrode 212, a capping layer (not illustrated) for the lower electrode 204 and the upper electrode 212, and a layer of at least one selected from the group consisting of Al, Al—Cu, Cu, Ag, and Au provided between the foundation layer and the capping layer. For example, the lower electrode 204 and the upper electrode 212 include tantalum (Ta)/copper (Cu)/tantalum (Ta), etc. For example, by using Ta as the foundation layer of the lower electrode 204 and the upper electrode 212, the adhesion between the substrate (e.g., the film) and the lower electrode 204 and between the substrate (e.g., the film) and the upper electrode 212 improves. Titanium (Ti), titanium nitride (TiN), etc., may be used as the foundation layer for the lower electrode 204 and the upper electrode 212.

By using Ta as the capping layer of the lower electrode 204 and the upper electrode 212, the oxidization of the copper (Cu), etc., under the capping layer is suppressed. Titanium (Ti), titanium nitride (TiN), etc., may be used as the capping layer for the lower electrode 204 and the upper electrode 212.

The foundation layer 205 includes, for example, a stacked structure including a buffer layer (not illustrated) and a seed layer (not illustrated). For example, the buffer layer relaxes the roughness of the surfaces of the lower electrode 204, the film, etc., and improves the crystallinity of the layers stacked on the buffer layer. For example, at least one selected from the group consisting of tantalum (Ta), titanium (Ti), vanadium (V), tungsten (W), zirconium (Zr), hafnium (Hf), and chrome (Cr) is used as the buffer layer. An alloy that includes at least one material selected from these materials may be used as the buffer layer.

It is favorable for the thickness of the buffer layer of the foundation layer 205 to be not less than 1 nm and not more than 10 nm. It is more favorable for the thickness of the buffer layer to be not less than 1 nm and not more than 5 nm. In the case where the thickness of the buffer layer is too thin, the buffering effect is lost. In the case where the thickness of the buffer layer is too thick, the thickness of the sensor portion 50A becomes excessively thick. The seed layer is formed on the buffer layer; and, for example, the seed layer has a buffering effect. In such a case, the buffer layer may be omitted. The buffer layer includes, for example, a Ta layer having a thickness of 3 nm.

The seed layer of the foundation layer 205 controls the crystal orientation of the layers stacked on the seed layer. The seed layer controls the crystal grain size of the layers stacked on the seed layer. As the seed layer, a metal having a fcc structure (a face-centered cubic structure), a hcp structure (a hexagonal close-packed structure), a bcc structure (a body-centered cubic structure), or the like is used.

For example, the crystal orientation of the spin-valve film on the seed layer can be set to the fcc (111) orientation by using, as the seed layer of the foundation layer 205, ruthenium (Ru) having a hcp structure, NiFe having a fcc structure, or Cu having a fcc structure. The seed layer includes, for example, a Cu layer having a thickness of 2 nm or a Ru layer having a thickness of 2 nm. To increase the crystal orientation of the layers formed on the seed layer, it is favorable for the thickness of the seed layer to be not less than 1 nm and not more than 5 nm. It is more favorable for the thickness of the seed layer to be not less than 1 nm and not more than 3 nm. Thereby, the function as a seed layer that improves the crystal orientation is realized sufficiently.

On the other hand, for example, the seed layer may be omitted in the case where it is unnecessary for the layers formed on the seed layer to have a crystal orientation (e.g., in the case where an amorphous free magnetic layer is formed, etc.). For example, a Cu layer having a thickness of 2 nm is used as the seed layer.

For example, the pinning layer 206 provides unidirectional anisotropy to the second magnetization reference layer 207 (the ferromagnetic layer) formed on the pinning layer 206 and fixes the magnetization of the second magnetization reference layer 207. The pinning layer 206 includes, for example, an antiferromagnetic layer. The pinning layer 206 includes, for example, at least one selected from the group consisting of Ir—Mn, Pt—Mn, Pd—Pt—Mn, Ru—Mn, Rh—Mn, Ru—Rh—Mn, Fe—Mn, Ni—Mn, Cr—Mn—Pt, and Ni—O. An alloy may be used in which an added element is further added to at least one selected from the group consisting of Ir—Mn, Pt—Mn, Pd—Pt—Mn, Ru—Mn, Rh—Mn, Ru—Rh—Mn, Fe—Mn, Ni—Mn, Cr—Mn—Pt, and Ni—O. The thickness of the pinning layer 206 is set appropriately. Thereby, for example, unidirectional anisotropy of sufficient strength is provided.

For example, heat treatment is performed while applying a magnetic field. Thereby, for example, the magnetization of the ferromagnetic layer contacting the pinning layer 206 is fixed. The magnetization of the ferromagnetic layer contacting the pinning layer 206 is fixed in the direction of the magnetic field applied in the heat treatment. For example, the heat treatment temperature (the annealing temperature) is not less than the magnetization pinning temperature of the antiferromagnetic material included in the pinning layer 206. In the case where an antiferromagnetic layer including Mn is used, there are cases where the MR ratio decreases due to the Mn diffusing into layers other than the pinning layer 206. It is desirable for the heat treatment temperature to be set to be not more than the temperature at which the diffusion of Mn occurs. The heat treatment temperature is, for example, not less than 200° C. and not more than 500° C. Favorably, the heat treatment temperature is, for example, not less than 250° C. and not more than 400° C.

In the case where PtMn or PdPtMn is used as the pinning layer 206, it is favorable for the thickness of the pinning layer 206 to be not less than 8 nm and not more than 20 nm. It is more favorable for the thickness of the pinning layer 206 to be not less than 10 nm and not more than 15 nm. In the case where IrMn is used as the pinning layer 206, unidirectional anisotropy can be provided using a thickness that is thinner than the case where PtMn is used as the pinning layer 206. In such a case, it is favorable for the thickness of the pinning layer 206 to be not less than 4 nm and not more than 18 nm. It is more favorable for the thickness of the pinning layer 206 to be not less than 5 nm and not more than 15 nm. The pinning layer 206 includes, for example, an Ir₂₂Mn₇₈ layer having a thickness of 7 nm.

A hard magnetic layer may be used as the pinning layer 206. For example, Co—Pt, Fe—Pt, Co—Pd, Fe—Pd, etc., may be used as the hard magnetic layer. For example, the magnetic anisotropy and the coercivity are relatively high for these materials. These materials are hard magnetic materials. An alloy in which an added element is further added to Co—Pt, Fe—Pt, Co—Pd, or Fe—Pd may be used as the pinning layer 206. For example, CoPt (the proportion of Co being not less than 50 at. % and not more than 85 at. %), (CoₓPt₁₀₀₋ₓ)_{100-y}Cr_{y} (x being not less than 50 at. % and not more than 85 at. %, and y being not less than 0 at. % and not more than 40 at. %), FePt (the proportion of Pt being not less than 40 at. % and not more than 60 at. %), etc., may be used.

The second magnetization reference layer 207 includes, for example, a CoₓFe₁₀₀₋ₓ alloy (x being not less than 0 at. % and not more than 100 at. %) or a NiₓFe₁₀₀₋ₓ alloy (x being not less than 0 at. % and not more than 100 at. %). These materials may include a material to which a nonmagnetic element is added. For example, at least one selected from the group consisting of Co, Fe, and Ni is used as the second magnetization reference layer 207. An alloy that includes at least one material selected from these materials may be used as the second magnetization reference layer 207. Also, a (CoₓFe₁₀₀₋ₓ)_{100-y}B_{y} alloy (x being not less than 0 at. % and not more than 100 at. %, and y being not less than 0 at. % and not more than 30 at. %) may be used as the second magnetization reference layer 207. By using an amorphous alloy of (CoₓFe_{100-31 x})_{100 -y}B_{y} as the second magnetization reference layer 207, the fluctuation of the characteristics of the sensor portion 50A can be suppressed even in the case where the sizes of the sensor portions are small.

For example, it is favorable for the thickness of the second magnetization reference layer 207 to be not less than 1.5 nm and not more than 5 nm. Thereby, for example, the strength of the unidirectional anisotropic magnetic field due to the pinning layer 206 can be stronger. For example, the strength of the antiferromagnetic coupling magnetic field between the second magnetization reference layer 207 and the first magnetization reference layer 209 via the magnetic coupling layer formed on the second magnetization reference layer 207 can be stronger. For example, it is favorable for the magnetic thickness (the product of the saturation magnetization and the thickness) of the second magnetization reference layer 207 to be substantially equal to the magnetic thickness of the first magnetization reference layer 209.

The saturation magnetization of the thin film of Co₄₀Fe₄₀B₂₀ is about 1.9 T (teslas). For example, in the case where a Co₄₀Fe₄₀B₂₀ layer having a thickness of 3 nm is used as the first magnetization reference layer 209, the magnetic thickness of the first magnetization reference layer 209 is 1.9 T×3 nm, i.e., 5.7 Tnm. On the other hand, the saturation magnetization of Co₇₅Fe₂₅ is about 2.1 T. The thickness of the second magnetization reference layer 207 to obtain a magnetic thickness equal to that recited above is 5.7 Tnm/2.1 T, i.e., 2.7 nm. In such a case, it is favorable for a Co₇₅Fe₂₅ layer having a thickness of about 2.7 nm to be included in the second magnetization reference layer 207. For example, a Co₇₅Fe₂₅ layer having a thickness of 2.5 nm is used as the second magnetization reference layer 207.

In the sensor portion 50A, a synthetic pinned structure that is made of the second magnetization reference layer 207, the magnetic coupling layer 208, and the first magnetization reference layer 209 is used. A single pinned structure that is made of one magnetization reference layer may be used instead. In the case where the single pinned structure is used, for example, a Co₄₀Fe₄₀B₂₀ layer having a thickness of 3 nm is used as the magnetization reference layer. The same material as the material of the second magnetization reference layer 207 described above may be used as the ferromagnetic layer included in the magnetization reference layer having the single pinned structure.

The magnetic coupling layer 208 causes antiferromagnetic coupling to occur between the second magnetization reference layer 207 and the first magnetization reference layer 209. The magnetic coupling layer 208 has a synthetic pinned structure. For example, Ru is used as the material of the magnetic coupling layer 208. For example, it is favorable for the thickness of the magnetic coupling layer 208 to be not less than 0.8 nm and not more than 1 nm. A material other than Ru may be used as the magnetic coupling layer 208 if the material causes sufficient antiferromagnetic coupling to occur between the second magnetization reference layer 207 and the first magnetization reference layer 209. For example, the thickness of the magnetic coupling layer 208 is set to a thickness not less than 0.8 nm and not more than 1 nm corresponding to the second peak (2nd peak) of RKKY (Ruderman-Kittel-Kasuya-Yosida) coupling. Further, the thickness of the magnetic coupling layer 208 may be set to a thickness not less than 0.3 nm and not more than 0.6 nm corresponding to the first peak (1st peak) of RKKY coupling. For example, Ru having a thickness of 0.9 nm is used as the material of the magnetic coupling layer 208. Thereby, highly reliable coupling is obtained more stably.

The magnetic layer that is included in the first magnetization reference layer 209 contributes directly to the MR effect. For example, a Co—Fe—B alloy is used as the first magnetization reference layer 209. Specifically, a (CoₓFe₁₀₀₋ₓ)_{100-y}B_{y} alloy (x being not less than 0 at. % and not more than 100 at. %, and y being not less than 0 at. % and not more than 30 at. %) also may be used as the first magnetization reference layer 209. For example, the fluctuation between the elements caused by crystal grains can be suppressed even in the case where the size of the sensor portion 50A is small by using a (CoₓFe₁₀₀₋ₓ)_{100-y}B_{y} amorphous alloy as the first magnetization reference layer 209.

The layer (e.g., the tunneling insulating layer (not illustrated)) that is formed on the first magnetization reference layer 209 can be planarized. The defect density of the tunneling insulating layer can be reduced by the planarization of the tunneling insulating layer. Thereby, a higher MR ratio is obtained with a lower resistance per area. For example, in the case where MgO is used as the material of the tunneling insulating layer, the (100) orientation of the MgO layer formed on the tunneling insulating layer can be strengthened by using a (CoₓFe₁₀₀₋ₓ)_{100-y}B_{y} amorphous alloy as the first magnetization reference layer 209. A higher MR ratio is obtained by increasing the (100) orientation of the MgO layer. The (CoₓFe₁₀₀₋ₓ)_{100-y}B_{y} alloy crystallizes using the (100) plane of the MgO layer as a template when annealing. Therefore, good crystal conformation between the MgO and the (CoₓFe₁₀₀₋ₓ)_{100-y}B_{y} alloy is obtained. A higher MR ratio is obtained by obtaining good crystal conformation.

Other than the Co—Fe—B alloy, for example, an Fe—Co alloy may be used as the first magnetization reference layer 209.

A higher MR ratio is obtained as the thickness of the first magnetization reference layer 209 increases. For example, a larger fixed magnetic field is obtained as the thickness of the first magnetization reference layer 209 decreases. A trade-off relationship between the MR ratio and the fixed magnetic field exists for the thickness of the first magnetization reference layer 209. In the case where the Co—Fe—B alloy is used as the first magnetization reference layer 209, it is favorable for the thickness of the first magnetization reference layer 209 to be not less than 1.5 nm and not more than 5 nm. It is more favorable for the thickness of the first magnetization reference layer 209 to be not less than 2.0 nm and not more than 4 nm.

Other than the materials described above, the first magnetization reference layer 209 may include a Co₉₀Fe₁₀ alloy having a fcc structure, Co having a hcp structure, or a Co alloy having a hcp structure. For example, at least one selected from the group consisting of Co, Fe, and Ni is used as the first magnetization reference layer 209. An alloy that includes at least one material selected from these materials is used as the first magnetization reference layer 209. For example, a higher MR ratio is obtained by using an FeCo alloy material having a bcc structure, a Co alloy having a cobalt composition of 50% or more, or a material (a Ni alloy) having a Ni composition of 50% or more as the first magnetization reference layer 209.

For example, a Heusler magnetic alloy layer such as Co₂MnGe, Co₂FeGe, Co₂MnSi, Co₂FeSi, Co₂MnAl, Co₂FeAl, Co₂MnGa_{0.5}Ge_{0.5}, Co₂FeGa_{0.5}Ge_{0.5}, etc., also may be used as the first magnetization reference layer 209. For example, a Co₄₀Fe₄₀B₂₀ layer having a thickness of, for example, 3 nm is used as the first magnetization reference layer 209.

For example, the intermediate layer 203 breaks the magnetic coupling between the first magnetization reference layer 209 and the free magnetic layer 210.

For example, the material of the intermediate layer 203 includes a metal, an insulator, or a semiconductor. For example, Cu, Au, Ag, or the like is used as the metal. In the case where a metal is used as the intermediate layer 203, the thickness of the intermediate layer is, for example, not less than about 1 nm and not more than about 7 nm. For example, magnesium oxide (MgO, etc.), aluminum oxide (Al₂O₃, etc.), titanium oxide (TiO, etc.), zinc oxide (ZnO, etc.), gallium oxide (Ga—O), or the like is used as the insulator or the semiconductor. In the case where the insulator or the semiconductor is used as the intermediate layer 203, the thickness of the intermediate layer 203 is, for example, not less than about 0.6 nm and not more than about 2.5 nm. For example, a CCP (Current-Confined-Path) spacer layer may be used as the intermediate layer 203. In the case where a CCP spacer layer is used as the spacer layer, for example, a structure is used in which a copper (Cu) metal path is formed inside an insulating layer of aluminum oxide (Al₂O₃). For example, a MgO layer having a thickness of 1.6 nm is used as the intermediate layer.

The free magnetic layer 210 includes a ferromagnet material. For example, the free magnetic layer 210 includes a ferromagnet material including Fe, Co, and Ni. For example, an FeCo alloy, a NiFe alloy, or the like is used as the material of the free magnetic layer 210. Further, the free magnetic layer 210 includes a Co—Fe—B alloy, an Fe—Co—Si—B alloy, an Fe—Ga alloy having a large λs (magnetostriction constant), an Fe—Co—Ga alloy, a Tb-M-Fe alloy, a Tb-M1-Fe-M2 alloy, an Fe-M3-M4-B alloy, Ni, Fe—Al, ferrite, etc. For example, the λs (the magnetostriction constant) is large for these materials. In the Tb-M-Fe alloy recited above, M is at least one selected from the group consisting of Sm, Eu, Gd, Dy, Ho, and Er. In the Tb-M1-Fe-M2 alloy recited above, M1 is at least one selected from the group consisting of Sm, Eu, Gd, Dy, Ho, and Er. M2 is at least one selected from the group consisting of Ti, Cr, Mn, Co, Cu, Nb, Mo, W, and Ta. In the Fe-M3-M4-B alloy recited above, M3 is at least one selected from the group consisting of Ti, Cr, Mn, Co, Cu, Nb, Mo, W, and Ta. M4 is at least one selected from the group consisting of Ce, Pr, Nd, Sm, Tb, Dy, and Er. Fe₃O₄, (FeCo)₃O₄, etc., are examples of the ferrite recited above. The thickness of the free magnetic layer 210 is, for example, 2 nm or more.

The free magnetic layer 210 may include a magnetic material including boron. The free magnetic layer 210 may include, for example, an alloy including boron (B) and at least one element selected from the group consisting of Fe, Co, and Ni. The free magnetic layer 210 includes, for example, a Co—Fe—B alloy or an Fe—B alloy. For example, a Co₄₀Fe₄₀B₂₀ alloy is used. Ga, Al, Si, W, etc., may be added in the case where the free magnetic layer 210 includes an alloy including boron (B) and at least one element selected from the group consisting of Fe, Co, and Ni. For example, high magnetostriction is promoted by adding these elements. For example, an Fe—Ga—B alloy, an Fe—Co—Ga—B alloy, or an Fe—Co—Si—B alloy may be used as the free magnetic layer 210. By using such a magnetic material including boron, the coercivity (Hc) of the free magnetic layer 210 is low; and the change of the magnetization direction for the strain is easy. Thereby, high sensitivity is obtained.

It is favorable for the boron concentration (e.g., the composition ratio of boron) of the free magnetic layer 210 to be 5 at. % (atomic percent) or more. Thereby, an amorphous structure is easier to obtain. It is favorable for the boron concentration of the free magnetic layer to be 35 at. % or less. For example, the magnetostriction constant decreases when the boron concentration is too high. For example, it is favorable for the boron concentration of the free magnetic layer to be not less than 5 at. % and not more than 35 at. %; and it is more favorable to be not less than 10 at. % and not more than 30 at. %.

In the case where a portion of the magnetic layer of the free magnetic layer 210 includes Fe_{1-y}B_{y} (0<y≤0.3) or (Fe_{z}X_{1-z})_{1-y}B_{y} (X being Co or Ni, 0.8≤z<1, and 0<y≤0.3), it is easy to realize both a large magnetostriction constant λ and a low coercivity. Therefore, this is particularly favorable from the perspective of obtaining a high gauge factor. For example, Fe₈₀B₂₀ (4 nm) is used as the free magnetic layer 210. Co₄₀Fe₄₀B₂₀ (0.5 nm)/Fe₈₀B₂₀ (4 nm) is used as the free magnetic layer.

The free magnetic layer 210 may have a multilayered structure. In the case where a tunneling insulating layer of MgO is used as the intermediate layer 203, it is favorable to provide a layer of a Co—Fe—B alloy at the portion of the free magnetic layer 210 contacting the intermediate layer 203. Thereby, a high magnetoresistance effect is obtained. In such a case, a layer of a Co—Fe—B alloy is provided on the intermediate layer 203; and another magnetic material that has a large magnetostriction constant is provided on the layer of the Co—Fe—B alloy. In the case where the free magnetic layer 210 has the multilayered structure, for example, the free magnetic layer 210 includes Co—Fe—B (2 nm)/Fe—Co—Si—B (4 nm), etc.

The capping layer 211 protects the layers provided under the capping layer 211. The capping layer 211 includes, for example, multiple metal layers. The capping layer 211 includes, for example, a two-layer structure (Ta/Ru) of a Ta layer and a Ru layer. The thickness of the Ta layer is, for example, 1 nm; and the thickness of the Ru layer is, for example, 5 nm. As the capping layer 211, another metal layer may be provided instead of the Ta layer and/or the Ru layer. The configuration of the capping layer 211 is arbitrary. For example, a nonmagnetic material is used as the capping layer 211. Another material may be used as the capping layer 211 as long as the material can protect the layers provided under the capping layer 211.

In the case where the free magnetic layer 210 includes a magnetic material including boron, a diffusion suppression layer (not illustrated) of an oxide material and/or a nitride material may be provided between the free magnetic layer 210 and the capping layer 211. Thereby, for example, the diffusion of boron is suppressed. By using the diffusion suppression layer including an oxide layer or a nitride layer, the diffusion of the boron included in the free magnetic layer 210 can be suppressed; and the amorphous structure of the free magnetic layer 210 can be maintained. As the oxide material and/or the nitride material included in the diffusion suppression layer, for example, an oxide material or a nitride material including an element such as Mg, Al, Si, Ti, V, Cr, Mn, Fe, Co, Ni, Cu, Zn, Zr, Nb, Mo, Ru, Rh, Pd, Ag, Hf, Ta, W, Sn, Cd, Ga, or the like is used. The diffusion suppression layer is a layer that does not contribute to the magnetoresistance effect. It is favorable for the resistance per area of the diffusion suppression layer to be low. For example, it is favorable for the resistance per area of the diffusion suppression layer to be set to be lower than the resistance per area of the intermediate layer that contributes to the magnetoresistance effect. From the perspective of reducing the resistance per area of the diffusion suppression layer, it is favorable for the diffusion suppression layer to be an oxide or a nitride of Mg, Ti, V, Zn, Sn, Cd, and Ga. The barrier height is low for these materials. It is favorable to use an oxide having a stronger chemical bond to suppress the diffusion of boron. For example, a MgO layer of 1.5 nm is used. Oxynitrides are included in one of the oxide or the nitride.

In the case where the diffusion suppression layer includes an oxide or a nitride, it is favorable for the thickness of the diffusion suppression layer to be, for example, 0.5 nm or more. Thereby, the diffusion suppression function of the boron is realized sufficiently. It is favorable for the thickness of the diffusion suppression layer to be 5 nm or less. Thereby, for example, a low resistance per area is obtained. It is favorable for the thickness of the diffusion suppression layer to be not less than 0.5 nm and not more than 5 nm; and it is favorable to be not less than 1 nm and not more than 3 nm.

At least one selected from the group consisting of magnesium (Mg), silicon (Si), and aluminum (Al) may be used as the diffusion suppression layer. A material that includes these light elements is used as the diffusion suppression layer. These light elements produce compounds by bonding with boron. For example, at least one of a Mg—B compound, an Al—B compound, or a Si—B compound is formed at the portion including the interface between the diffusion suppression layer and the free magnetic layer 210. These compounds suppress the diffusion of boron.

Another metal layer, etc., may be inserted between the diffusion suppression layer and the free magnetic layer 210. In the case where the distance between the diffusion suppression layer and the free magnetic layer 210 is too long, boron diffuses between the diffusion suppression layer and the free magnetic layer 210; and the boron concentration in the free magnetic layer 210 undesirably decreases. Therefore, it is favorable for the distance between the diffusion suppression layer and the free magnetic layer 210 to be 10 nm or less; and it is more favorable to be 3 nm or less.

FIG. 9 is a schematic perspective view illustrating a portion of another sensor according to the embodiment.

As shown in FIG. 9, other than an insulating layer 213 being provided, the sensor portion 50AA is similar to the sensor portion 50A. The insulating layer 213 is provided between the lower electrode 204 and the upper electrode 212. The insulating layer 213 is arranged with the free magnetic layer 210 and the first magnetization reference layer 209 in a direction crossing the direction connecting the lower electrode 204 and the upper electrode 212. Portions other than the insulating layer 213 are similar to those of the sensor portion 50A; and a description is therefore omitted.

The insulating layer 213 includes, for example, aluminum oxide (e.g., Al₂O₃), silicon oxide (e.g., SiO₂), etc. The leakage current of the sensor portion 50AA is suppressed by the insulating layer 213. The insulating layer 213 may be provided in the sensor portions described below.

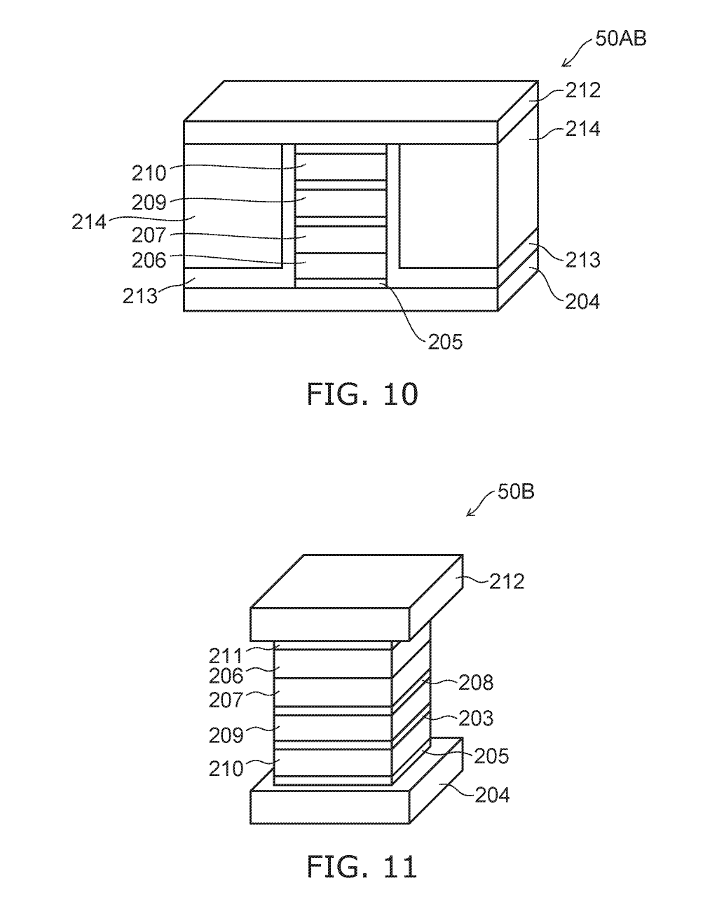

FIG. 10 is a schematic perspective view illustrating a portion of another sensor according to the embodiment. As shown in FIG. 10, a hard bias layer 214 is further provided in the sensor portion 50AB. Otherwise, the sensor portion 50AB is similar to the sensor portion 50A. The hard bias layer 214 is provided between the lower electrode 204 and the upper electrode 212. The free magnetic layer 210 and the first magnetization reference layer 209 are provided between two portions of the hard bias layer 214 in a direction crossing the direction connecting between the lower electrode 204 and the upper electrode 212. Otherwise, the sensor portion 50AB is similar to the sensor portion 50AA.

The hard bias layer 214 sets the magnetization direction of the free magnetic layer 210 by the magnetization of the hard bias layer 214. The magnetization direction of the free magnetic layer 210 is set to the desired direction by the hard bias layer 214 in a state in which pressure from the outside is not applied to the film.

The hard bias layer 214 includes, for example, Co—Pt, Fe—Pt, Co—Pd, Fe—Pd, etc. For example, the magnetic anisotropy and the coercivity are relatively high for these materials. These materials are, for example, hard magnetic materials. The hard bias layer 214 may include, for example, an alloy in which an added element is further added to Co—Pt, Fe—Pt, Co—Pd, or Fe—Pd. The hard bias layer 214 may include, for example, CoPt (the proportion of Co being not less than 50 at. % and not more than 85 at. %), (CoₓPt₁₀₀₋ₓ)_{100-y}Cr_{y} (x being not less than 50 at. % and not more than 85 at. %, and y being not less than 0 at. % and not more than 40 at. %), FePt (the proportion of Pt being not less than 40 at. % and not more than 60 at. %), etc. In the case where such a material is used, the direction of the magnetization of the hard bias layer 214 is set (fixed) to the direction in which the external magnetic field is applied by applying an external magnetic field that is larger than the coercivity of the hard bias layer 214. The thickness of the hard bias layer 214 (e.g., the length along the direction from the lower electrode 204 toward the upper electrode) is, for example, not less than 5 nm and not more than 50 nm.

In the case where the insulating layer 213 is provided between the lower electrode 204 and the upper electrode 212, SiOₓ or AlOₓ is used as the material of the insulating layer 213. A not-illustrated foundation layer may be further provided between the insulating layer 213 and the hard bias layer 214. Cr, Fe—Co, or the like is used as the material of the foundation layer for the hard bias layer 214 in the case where the hard bias layer 214 includes a hard magnetic material such as Co—Pt, Fe—Pt, Co—Pd, Fe—Pd, etc.

The hard bias layer 214 may have a structure in which a not-illustrated hard bias-layer pinning layer is stacked. In such a case, the direction of the magnetization of the hard bias layer 214 can be set (fixed) by the exchange coupling of the hard bias layer 214 and the hard bias-layer pinning layer. In such a case, the hard bias layer 214 includes a ferromagnetic material of at least one selected from the group consisting of Fe, Co, and Ni, or an alloy including at least one type of these elements. In such a case, the hard bias layer 214 includes, for example, a CoₓFe₁₀₀₋ₓ alloy (x being not less than 0 at. % and not more than 100 at. %), a NiₓFe_{100 -x} alloy (x being not less than 0 at. % and not more than 100 at. %), or a material in which a nonmagnetic element is added to these alloys. A material similar to the first magnetization reference layer 209 recited above is used as the hard bias layer 214. The hard bias-layer pinning layer includes a material similar to the pinning layer 206 inside the sensor portion 50A recited above. In the case where the hard bias-layer pinning layer is provided, a foundation layer similar to the material included in the foundation layer 205 may be provided under the hard bias-layer pinning layer. The hard bias-layer pinning layer may be provided at the lower portion or the upper portion of the hard bias layer. In such a case, the magnetization direction of the hard bias layer 214 is determined by heat treatment in a magnetic field similarly to the pinning layer 206.

The hard bias layer 214 and the insulating layer 213 recited above are applicable also to any sensor portion according to the embodiments. By using the stacked structure of the hard bias layer 214 and the hard bias-layer pinning layer, the orientation of the magnetization of the hard bias layer 214 can be maintained easily even in the case where a large external magnetic field is applied to the hard bias layer 214 in a short length of time.

FIG. 11 is a schematic perspective view illustrating a portion of another sensor according to the embodiment. In the sensor portion 50B as shown in FIG. 11, the lower electrode 204, the foundation layer 205, the free magnetic layer 210, the intermediate layer 203, the first magnetization reference layer 209, the magnetic coupling layer 208, the second magnetization reference layer 207, the pinning layer 206, the capping layer 211, and the upper electrode 212 are stacked in order. The sensor portion 50B is, for example, a top spin-valve type.

The foundation layer 205 includes, for example, a stacked film of tantalum and copper (Ta/Cu). The thickness (the length in the Z-axis direction) of the Ta layer is, for example, 3 nm. The thickness of the Cu layer is, for example, 5 nm. The free magnetic layer 210 includes, for example, Co₄₀Fe₄₀B₂₀ having a thickness of 4 nm. The intermediate layer 203 includes, for example, a MgO layer having a thickness of 1.6 nm. The first magnetization reference layer 209 includes, for example, Co₄₀Fe₄₀B₂₀/Fe₅₀Co₅₀. The thickness of the Co₄₀Fe₄₀B₂₀ layer is, for example, 2 nm. The thickness of the Fe₅₀Co₅₀ layer is, for example, 1 nm. The magnetic coupling layer 208 includes, for example, a Ru layer having a thickness of 0.9 nm. The second magnetization reference layer 207 includes, for example, a Co₇₅Fe₂₅ layer having a thickness of 2.5 nm. The pinning layer 206 includes, for example, an IrMn-layer having a thickness of 7 nm. The capping layer 211 includes, for example, Ta/Ru. The thickness of the Ta layer is, for example, 1 nm. The thickness of the Ru layer is, for example, 5 nm.

The materials of the layers included in the sensor portion 50B may be the vertically inverted materials of the layers included in the sensor portion 50A. The diffusion suppression layer recited above may be provided between the foundation layer 205 and the free magnetic layer 210 of the sensor portion 50B.

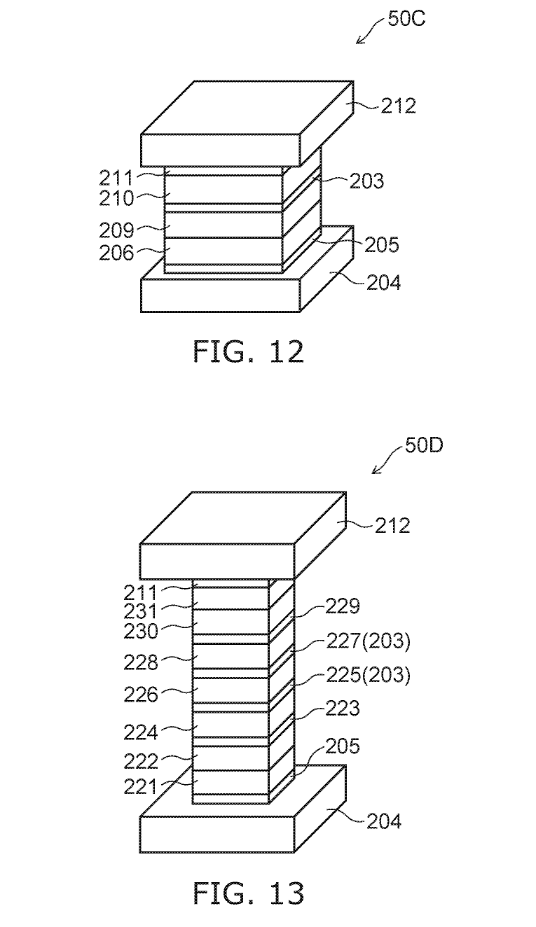

FIG. 12 is a schematic perspective view illustrating a portion of another sensor according to the embodiment.

In the sensor portion 50C as shown in FIG. 12, the lower electrode 204, the foundation layer 205, the pinning layer 206, the first magnetization reference layer 209, the intermediate layer 203, the free magnetic layer 210, and the capping layer 211 are stacked in this order. For example, the sensor portion 50C has a single pinned structure that uses a single magnetization reference layer.

The foundation layer 205 includes, for example, Ta/Ru. The thickness (the length in the Z-axis direction) of the Ta layer is, for example, 3 nm. The thickness of the Ru layer is, for example, 2 nm. The pinning layer 206 includes, for example, an IrMn-layer having a thickness of 7 nm. The first magnetization reference layer 209 includes, for example, a Co₄₀Fe₄₀B₂₀ layer having a thickness of 3 nm. The intermediate layer 203 includes, for example, a MgO layer having a thickness of 1.6 nm. The free magnetic layer 210 includes, for example, Co₄₀Fe₄₀B₂₀ having a thickness of 4 nm. The capping layer 211 includes, for example, Ta/Ru. The thickness of the Ta layer is, for example, 1 nm. The thickness of the Ru layer is, for example, 5 nm.

For example, materials similar to the materials of the layers of the sensor portion 50A are used as the materials of the layers of the sensor portion 50C.

FIG. 13 is a schematic perspective view illustrating a portion of another sensor according to the embodiment.

In the sensor portion 50D as shown in FIG. 13, the lower electrode 204, the foundation layer 205, a lower pinning layer 221, a lower second magnetization reference layer 222, a lower magnetic coupling layer 223, a lower first magnetization reference layer 224, a lower intermediate layer 225, a free magnetic layer 226, an upper intermediate layer 227, an upper first magnetization reference layer 228, an upper magnetic coupling layer 229, an upper second magnetization reference layer 230, an upper pinning layer 231, and the capping layer 211 are stacked in order.

The foundation layer 205 includes, for example, Ta/Ru. The thickness (the length in the Z-axis direction) of the Ta layer is, for example, 3 nanometers (nm). The thickness of the Ru layer is, for example, 2 nm. The lower pinning layer 221 includes, for example, an IrMn-layer having a thickness of 7 nm. The lower second magnetization reference layer 222 includes, for example, a Co₇₅Fe₂₅ layer having a thickness of 2.5 nm. The lower magnetic coupling layer 223 includes, for example, a Ru layer having a thickness of 0.9 nm. The lower first magnetization reference layer 224 includes, for example, a Co₄₀Fe₄₀B₂₀ layer having a thickness of 3 nm. The lower intermediate layer 225 includes, for example, a MgO layer having a thickness of 1.6 nm. The free magnetic layer 226 includes, for example, Co₄₀Fe₄₀B₂₀ having a thickness of 4 nm. The upper intermediate layer 227 includes, for example, a MgO layer having a thickness of 1.6 nm. The upper first magnetization reference layer 228 includes, for example, Co₄₀Fe₄₀B₂₀/Fe₅₀Co₅₀. The thickness of the Co₄₀Fe₄₀B₂₀ layer is, for example, 2 nm. The thickness of the Fe₅₀Co₅₀ layer is, for example, 1 nm. The upper magnetic coupling layer 229 includes, for example, a Ru layer having a thickness of 0.9 nm. The upper second magnetization reference layer 230 includes, for example, a Co₇₅Fe₂₅ layer having a thickness of 2.5 nm. The upper pinning layer 231 includes, for example, an IrMn-layer having a thickness of 7 nm. The capping layer 211 includes, for example, Ta/Ru. The thickness of the Ta layer is, for example, 1 nm. The thickness of the Ru layer is, for example, 5 nm.

For example, materials similar to the materials of the layers of the sensor portion 50A are used as the materials of the layers of the sensor portion 50D.

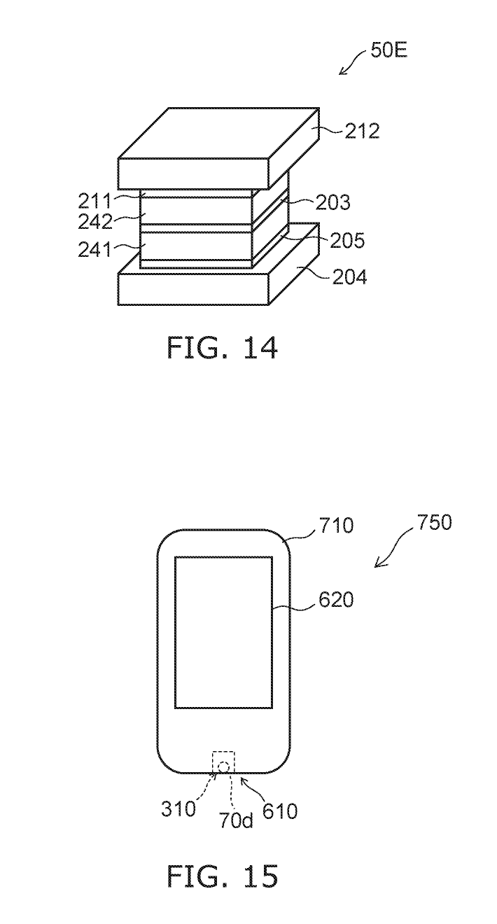

FIG. 14 is a schematic perspective view illustrating a portion of another sensor according to the embodiment.

In the sensor portion 50E as shown in FIG. 14, the lower electrode 204, the foundation layer 205, a first free magnetic layer 241, the intermediate layer 203, a second free magnetic layer 242, the capping layer 211, and the upper electrode 212 are stacked in this order.

The foundation layer 205 includes, for example, Ta/Cu. The thickness (the length in the Z-axis direction) of the Ta layer is, for example, 3 nm. The thickness of the Cu layer is, for example, 5 nm. The first free magnetic layer 241 includes, for example, Co₄₀Fe₄₀B₂₀ having a thickness of 4 nm. The intermediate layer 203 includes, for example, Co₄₀Fe₄₀B₂₀ having a thickness of 4 nm. The capping layer 211 includes, for example, Cu/Ta/Ru. The thickness of the Cu layer is, for example, 5 nm. The thickness of the Ta layer is, for example, 1 nm. The thickness of the Ru layer is, for example, 5 nm.

Materials similar to the materials of the layers of the sensor portion 50A are used as the materials of the layers of the sensor portion 50E. For example, materials similar to those of the free magnetic layer 210 of the sensor portion 50A may be used as the materials of the first free magnetic layer 241 and the second free magnetic layer 242.

### Second Embodiment

The embodiment relates to an electronic device. The electronic device includes, for example, a sensor or a modification of a sensor according to the embodiment recited above. The electronic device includes, for example, an information terminal. The information terminal includes a recorder, etc. The electronic device includes a microphone, a blood pressure sensor, a touch panel, etc.

FIG. 15 is a schematic view illustrating the electronic device according to the second embodiment.

As shown in FIG. 15, the electronic device 750 according to the embodiment is, for example, an information terminal 710. For example, a microphone 610 is provided in the information terminal 710.

The microphone 610 includes, for example, a sensor 310. For example, a first film 40 is substantially parallel to the surface where a displayer 620 of the information terminal 710 is provided. The arrangement of the first film 40 is arbitrary. Any sensor described in reference to the first embodiment is applied to the sensor 310.

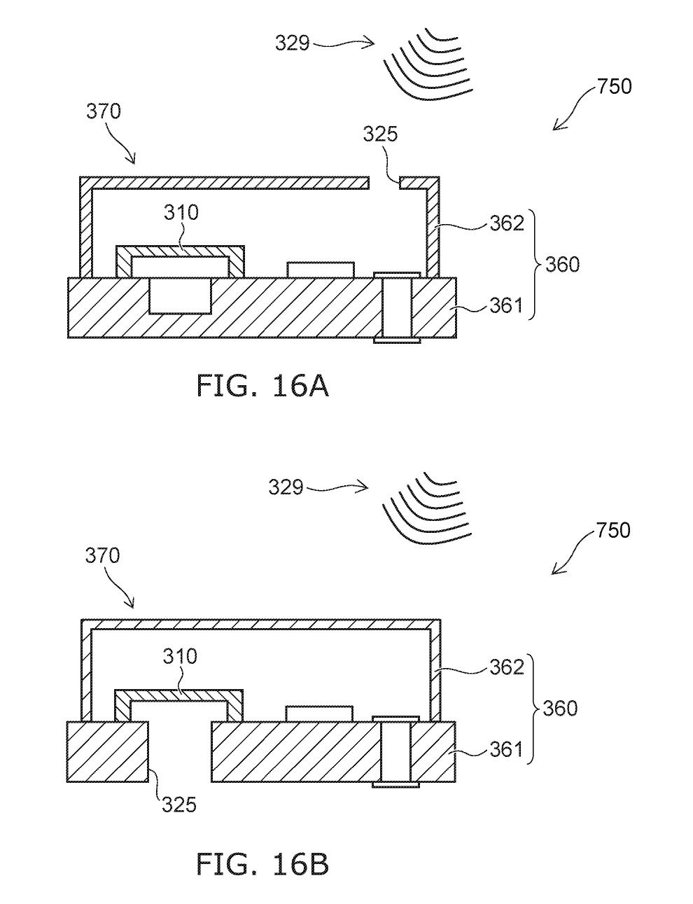

FIG. 16A and FIG. 16B are schematic cross-sectional views illustrating the electronic device according to the second embodiment.

As shown in FIG. 16A and FIG. 16B, the electronic device 750 (e.g., a microphone 370 (an acoustic microphone)) includes a housing 360, a cover 362, and the sensor 310. The housing 360 includes, for example, a substrate 361 (e.g., a printed circuit board) and the cover 362. The substrate 361 includes, for example, a circuit such as an amplifier, etc.

An acoustic hole 325 is provided in the housing 360 (at least one of the substrate 361 or the cover 362). In the example shown in FIG. 16B, the acoustic hole 325 is provided in the cover 362. In the example shown in FIG. 16B, the acoustic hole 325 is provided in the substrate 361. Sound 329 enters the interior of the cover 362 via the acoustic hole 325. The microphone 370 responds to the sound pressure.

For example, the sensor 310 is placed on the substrate 361; and an electrical signal line (not illustrated) is provided. The cover 362 is provided to cover the sensor 310. The housing 360 is provided around the sensor 310. At least a portion of the sensor 310 is provided inside the housing 360. For example, the first sensor portion 51 and the first film 40 are provided between the substrate 361 and the cover 362. For example, the sensor 310 is provided between the substrate 361 and the cover 362.

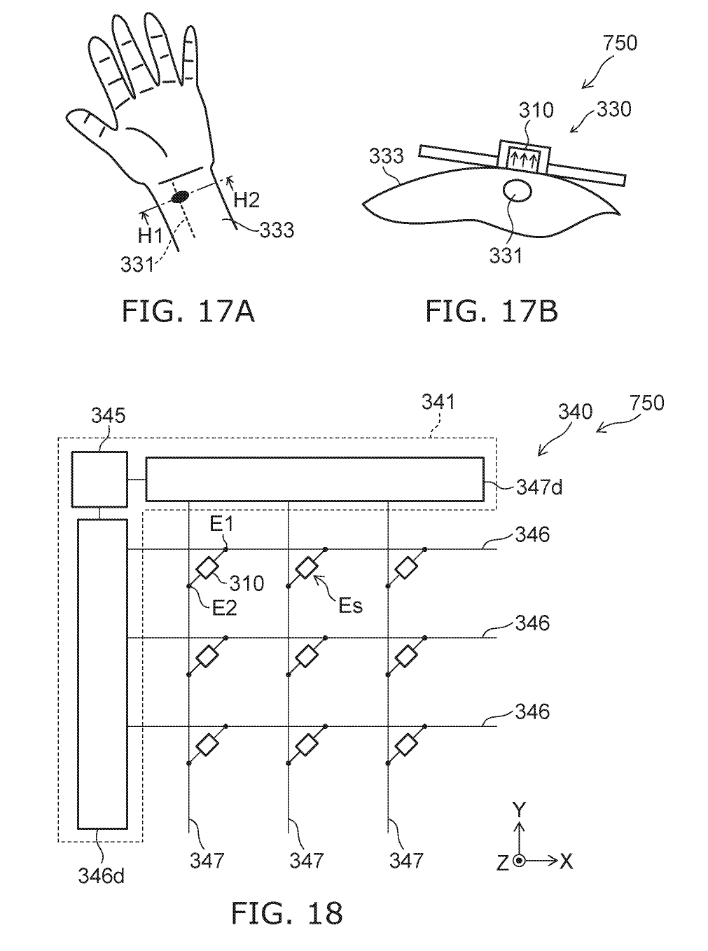

FIG. 17A and FIG. 17B are schematic views illustrating another electronic device according to the second embodiment.

In the example of these drawings, the electronic device 750 is a blood pressure sensor 330. FIG. 17A is a schematic plan view illustrating skin on an arterial vessel of a human. FIG. 17B is a line H1-H2 cross-sectional view of FIG. 17A.

The sensor 310 is used as the sensor of the blood pressure sensor 330. The sensor 310 contacts the skin 333 on the arterial vessel 331. Thereby, the blood pressure sensor 330 can continuously perform blood pressure measurements.

FIG. 18 is a schematic view illustrating another electronic device according to the second embodiment.

In the example of the drawing, the electronic device 750 is a touch panel 340. In the touch panel 340, the sensors 310 are provided in at least one of the interior of the display or the exterior of the display.

For example, the touch panel 340 includes multiple first interconnects 346, multiple second interconnects 347, the multiple sensors 310, and a control circuit 341.

In the example, the multiple first interconnects 346 are arranged along the Y-axis direction. Each of the multiple first interconnects 346 extends along the X-axis direction. The multiple second interconnects 347 are arranged along the X-axis direction. Each of the multiple second interconnects 347 extends along the Y-axis direction.

One of the multiple sensors 310 is provided at the crossing portion between the multiple first interconnects 346 and the multiple second interconnects 347. One of the sensors 310 is used as one of sensing components Es for sensing. The crossing portion includes the position where the first interconnect 346 and the second interconnect 347 cross and includes the region at the periphery of the position.

One end E1 of one of the multiple sensors 310 is connected to one of the multiple first interconnects 346. Another end E2 of the one of the multiple sensors 310 is connected to one of the multiple second interconnects 347.

The control circuit 341 is connected to the multiple first interconnects 346 and the multiple second interconnects 347. For example, the control circuit 341 includes a first interconnect circuit 346d that is connected to the multiple first interconnects 346, a second interconnect circuit 347d that is connected to the multiple second interconnects 347, and a control signal circuit 345 that is connected to the first interconnect circuit 346d and the second interconnect circuit 347d.

According to the second embodiment, an electronic device that uses a sensor in which the sensitivity can be increased can be provided.

The embodiments may include the following configurations (e.g., technological proposals).
Configuration 1
   A sensor, comprising:
   a film portion including a first film including multiple holes, the film portion being deformable; and
   a first sensor portion fixed to a portion of the film portion, the first sensor portion including
      a first magnetic layer,
      a second magnetic layer provided between the first film and the first magnetic layer, and
      a first intermediate layer provided between the first magnetic layer and the second magnetic layer,
   a direction from at least a portion of the multiple holes toward the first sensor portion being aligned with a first direction, the first direction being from the first film toward the first sensor portion.
Configuration 2
   The sensor according to Configuration 1, wherein
   the film portion further includes a second film,
   a direction from the first film toward the second film is aligned with the first direction, and
   a density of the first film is lower than a density of the second film.
Configuration 3
   The sensor according to Configuration 1, wherein
   the film portion further includes a second film,
   a direction from the first film toward the second film is aligned with the first direction, and
   the second film substantially does not include a hole.
Configuration 4
   The sensor according to Configuration 1, wherein
   the film portion further includes a second film including multiple holes,
   a direction from the first film toward the second film is aligned with the first direction, and
   a density of the multiple holes inside the first film is higher than a density of the multiple holes inside the second film.
Configuration 5
   The sensor according to Configuration 1, wherein
   the film portion further includes a second film,
   a direction from the first film toward the second film is aligned with the first direction, and
   a porosity of the first film is higher than a porosity of the second film.
Configuration 6
   The sensor according to Configuration 1, wherein
   the film portion further includes a second film,
   a direction from the first film toward the second film is aligned with the first direction, and
   a surface roughness of a cross section of the first film is rougher than a surface roughness of a cross section of the second film.
Configuration 7

The sensor according to any one of Configurations 2 to 6, wherein a thickness along the first direction of the first film is thicker than a thickness along the first direction of the second film.
Configuration 8
   The sensor according to Configuration 2, wherein
   the film portion further includes a third film,
   a position in the first direction of the first film is between a position in the first direction of the second film and a position in the first direction of the third film, and
   the density of the first film is lower than a density of the third film.
Configuration 9
   The sensor according to any one of Configurations 2 to 7, wherein
   the film portion further includes a third film,
   a position in the first direction of the first film is between a position in the first direction of the second film and a position in the first direction of the third film, and
   the third film substantially does not include a hole.
Configuration 10
   The sensor according to Configuration 4, wherein
   the film portion further includes a third film including multiple holes,
   a position in the first direction of the first film is between a position in the first direction of the second film and a position in the first direction of the third film, and
   the density of the multiple holes inside the first film is higher than a density of the multiple holes inside the third film.
Configuration 11
   The sensor according to Configuration 5, wherein
   the film portion further includes a third film,
   a position in the first direction of the first film is between a position in the first direction of the second film and a position in the first direction of the third film, and
   the porosity of the first film is higher than a porosity of the third film.
Configuration 12
   The sensor according to Configuration 6, wherein
   the film portion further includes a third film,
   a position in the first direction of the first film is between a position in the first direction of the second film and a position in the first direction of the third film, and
   the surface roughness of the cross section of the first film is rougher than a surface roughness of a cross section of the third film.
Configuration 13
   The sensor according to any one of Configurations 2 to 12, wherein the second film includes at least one selected from the group consisting of silicon, silicon oxide, aluminum oxide, silicon nitride, aluminum silicate, and silicon oxynitride.
Configuration 14
   The sensor according to any one of Configurations 1 to 13, wherein the first film includes at least one selected from the group consisting of silicon oxide, aluminum oxide, titanium oxide, aluminum silicate, silicon oxynitride, and aluminophosphate.
Configuration 15
   The sensor according to any one of Configurations 1 to 15, wherein a porosity of the first film is 30% or more.
Configuration 16
   A sensor, comprising:
   a film portion including a first film including a metal compound portion and a carbon-including portion, the film portion being deformable; and
   a first sensor portion fixed to a portion of the film portion, the first sensor portion including
      a first magnetic layer,
      a second magnetic layer provided between the first film and the first magnetic layer, and
      a first intermediate layer provided between the first magnetic layer and the second magnetic layer,
   a direction from at least a portion of the metal compound portion toward at least a portion of the carbon-including portion crossing a first direction from the first film toward the first sensor portion.
Configuration 17
   The sensor according to Configuration 16, wherein
   the metal compound portion includes at least one selected from the group consisting of an oxide, a nitride, and an oxynitride,
   the oxide includes at least one selected from the group consisting of silicon, aluminum, titanium, and tungsten,
   the nitride includes at least one selected from the group consisting of silicon, aluminum, titanium, and tungsten, and
   the oxynitride includes at least one selected from the group consisting of silicon, aluminum, titanium, and tungsten.
Configuration 18
   The sensor according to Configuration 16 or 17, wherein the carbon-including portion includes at least one selected from the group consisting of a hydroxy group, a carbonyl group, a carboxy group, an ether bond, an ester bond, an amine, and an imine.
Configuration 19
   The sensor according to any one of Configurations 2 to 13, further comprising:
   a first member having an opening; and
   a second member,
   the first sensor portion and the film portion being provided between the first member and the second member,
   at least a portion of the second film being positioned between the opening and at least a portion of the first film.

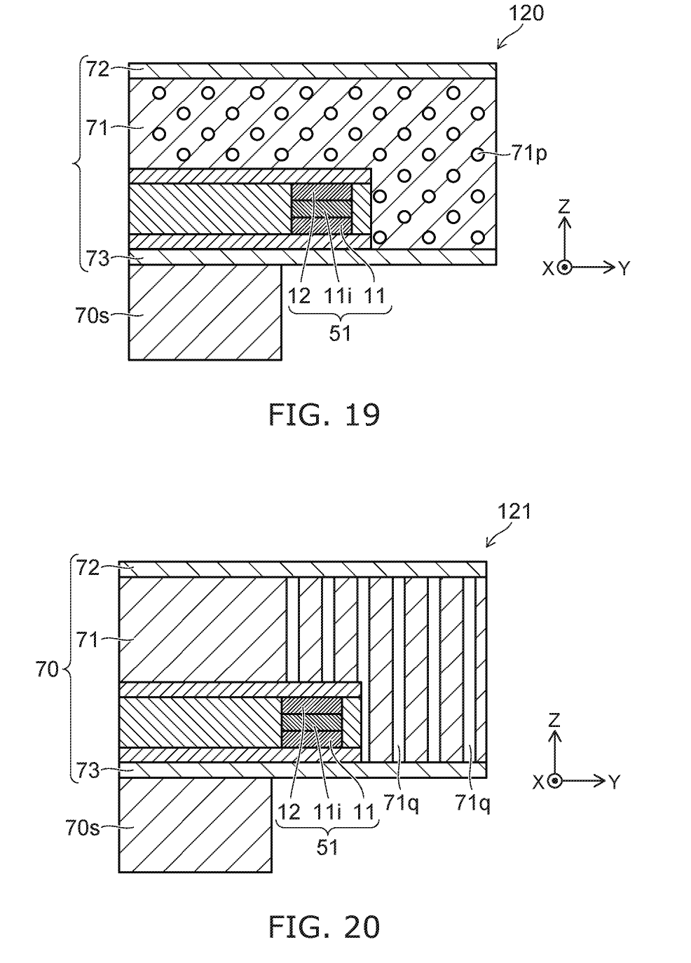

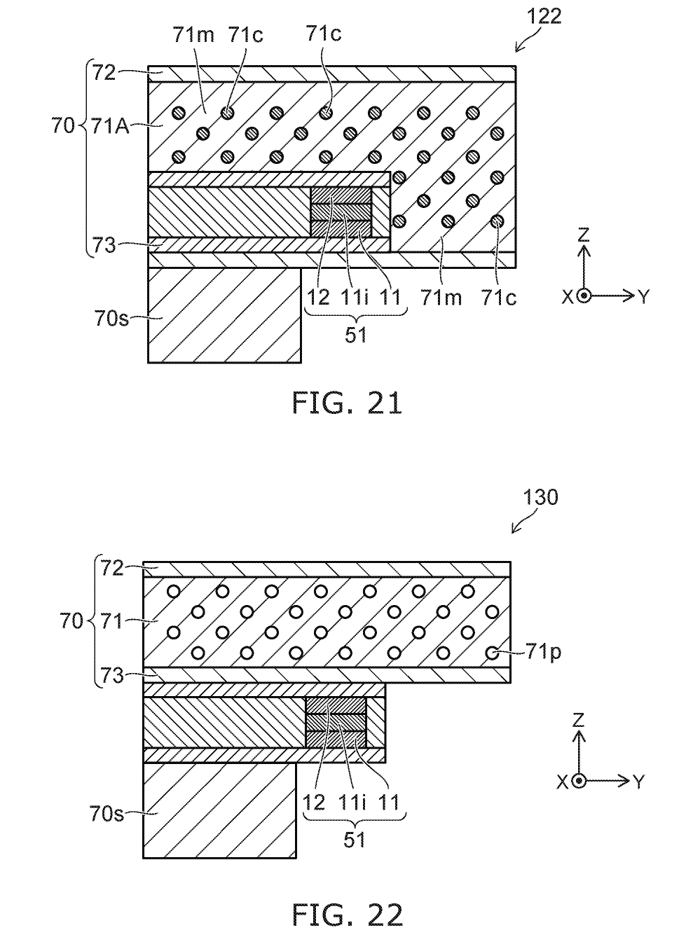

FIGS. 19-21 are schematic cross-sectional views illustrating a portion of another sensor according to the embodiment.

FIGS. 19-21 correspond to the cross-sectional view shown in FIG. 1C.

In a sensor 120, the position of the first sensor portion 51 in the Z-axis direction is different from that in the sensor 110. Other than this, the sensor 120 is same as the sensor 110. In a sensor 121, the position of the first sensor portion 51 in the Z-axis direction is different from that in the sensor 112. Other than this, the sensor 121 is same as the sensor 112. In a sensor 122, the position of the first sensor portion 51 in the Z-axis direction is different from that in the sensor 113. Other than this, the sensor 122 is same as the sensor 113. In the sensors 120-122, the position of the first sensor portion 51 in the Z-axis direction is between the position of the supporter 70s in the Z-axis direction and the positon of a part of the first film 71 (or the first film 71A) in the Z-axis direction. The first sensor portion 51 is provided between the above-mentioned part of the first film 71 (or the first film 71A) and the third film 73.

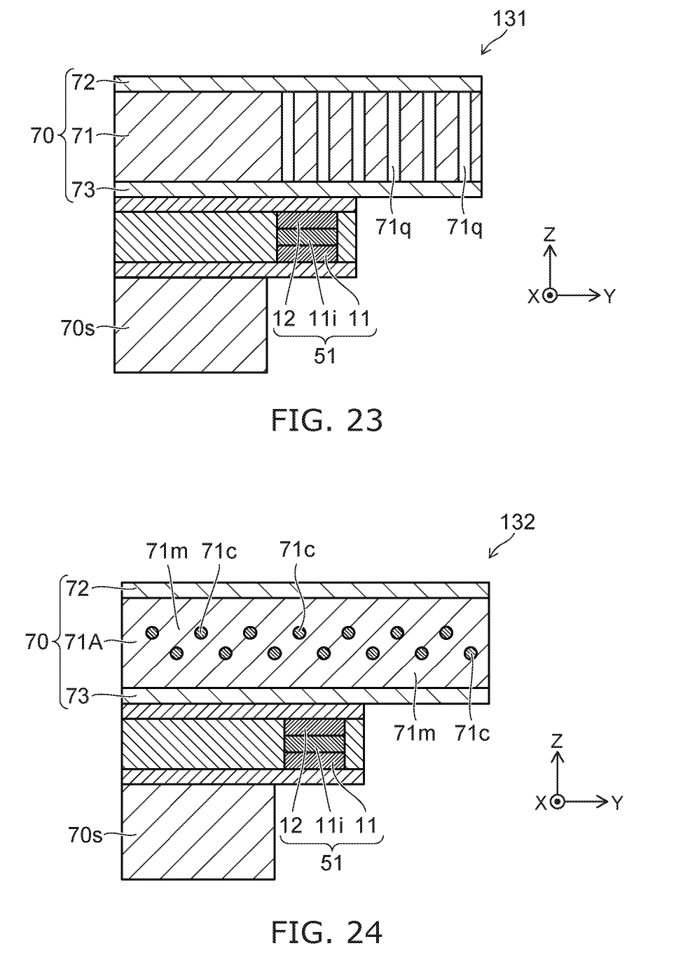

FIGS. 22-24 are schematic cross-sectional views illustrating a portion of another sensor according to the embodiment.

FIGS. 22-24 correspond to the cross-sectional view shown in FIG. 1C.

In a sensor 130, the position of the first sensor portion 51 in the Z-axis direction is different from that in the sensor 110. Other than this, the sensor 130 is same as the sensor 110. In a sensor 131, the position of the first sensor portion 51 in the Z-axis direction is different from that in the sensor 112. Other than this, the sensor 131 is same as the sensor 112. In a sensor 132, the position of the first sensor portion 51 in the Z-axis direction is different from that in the sensor 113. Other than this, the sensor 132 is same as the sensor 113. In the sensors 130-132, the position of the first sensor portion 51 in the Z-axis direction is between the position of the supporter 70s in the Z-axis direction and the positon of the first film 71 (or the first film 71A) in the Z-axis direction.

In the manufacturing of the sensor 120-132, after the forming of the first sensor portion 51, at least a part of the film portion (the first film 71 or first film 71A) is formed, for example. The firming the first sensor portion includes a heat treatment at a high temperature. In a case where the film portion 70 is formed after the heat treatment, a damage of the film portion can be suppressed.

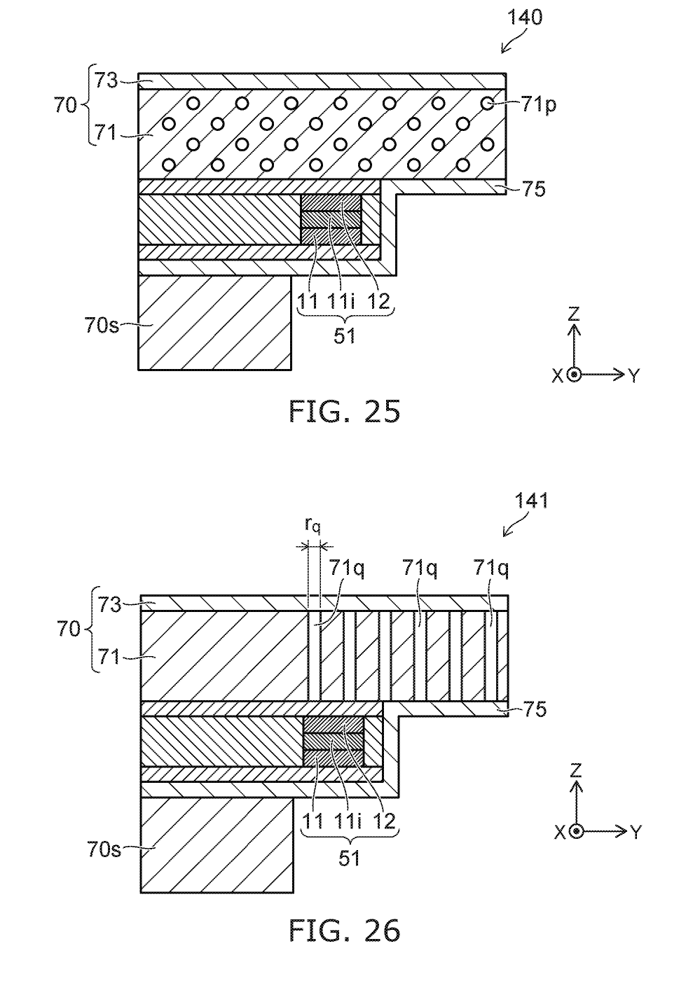

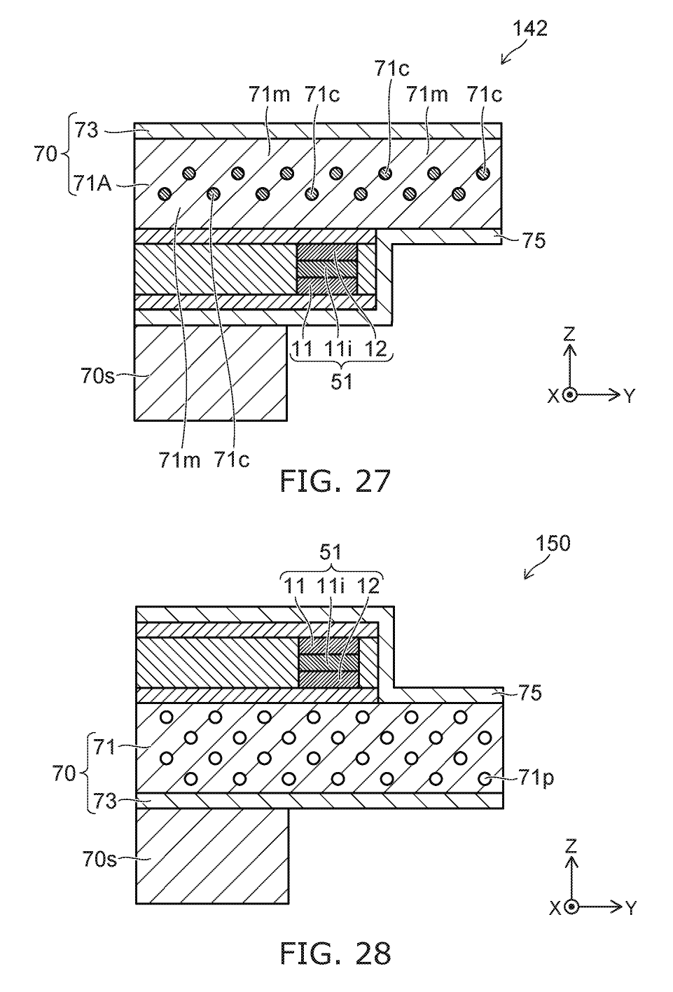

FIGS. 25-27 are schematic cross-sectional views illustrating a portion of another sensor according to the embodiment.

FIGS. 25-27 correspond to the cross-sectional view shown in FIG. 1C.

Sensors 140-142 include an insulating film 75 in addition to the film portion 70 and the first sensor portion 51. In the sensor 140, the position of the first sensor portion 51 in the Z-axis direction is different from that in the sensor 110. In the sensor 141, the position of the first sensor portion 51 in the Z-axis direction is different from that in the sensor 112. In the sensor 142, the position of the first sensor portion 51 in the Z-axis direction is different from that in the sensor 113. In the sensors 140-142, the position of the first sensor portion 51 in the Z-axis direction is between the position of the supporter 70s in the Z-axis direction and the positon of the first film 71 (or the first film 71A) in the Z-axis direction. The first sensor portion 51 is provided between the first film 71 (or the first film 71A) and the insulating film 75.

FIG. 28 is schematic cross-sectional views illustrating a portion of another sensor according to the embodiment.

FIG. 28 corresponds to the cross-sectional view shown in FIG. 1C. A sensor 150 includes the insulating film 75 in addition to the film portion 70 and the first sensor portion 51. The first sensor portion 51 is provided between a part of the insulating film 75 and the film portion 70. A part of the film portion 70 is located between a part of the insulating film 75 and the supporter 70s. The first film 71 is provided between another part of the insulating film 75 and the third film 73. The insulating film 75 protects the first sensor portion 51 and the film portion 70, for example.

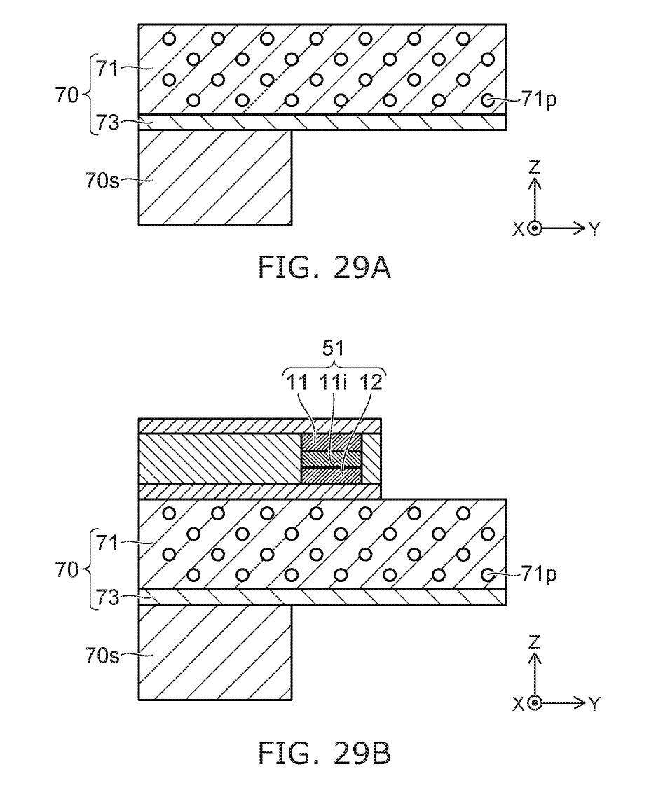

FIGS. 29A and 29B are schematic cross-sectional views illustrating a manufacturing method the sensor according to the embodiment.

As shown in FIG. 29A, the film potion 70 (in this example, the first film 71 and the third film 73) is formed. As shown in FIG. 29B, the first sensor portion 51 is formed. For example, in the forming the first sensor portion 51, a heat treatment is performed. After this, the insulating film 75 (referring to FIG. 28) is formed.

In this example, at least a part of the gas etc. included in the film portion 70 is removed in the heat treatment. By forming the insulating film 75 after the heat treatment, the gas is removed effectively.

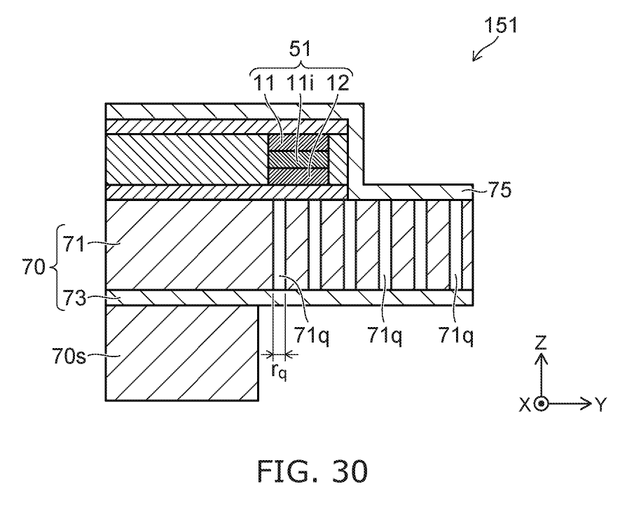

FIG. 30 is schematic cross-sectional views illustrating a portion of another sensor according to the embodiment.

FIG. 30 corresponds to the cross-sectional view shown in FIG. 1C. A sensor 151 includes the insulating film 75 in addition to the film portion 70 and the first sensor portion 51. The first sensor portion 51 is provided between a part of the insulating film 75 and the film portion 70. A part of the film portion 70 is located between a part of the insulating film 75 and the supporter 70s. The first film 71 is provided between another part of the insulating film 75 and the third film 73. The insulating film 75 protects the first sensor portion 51 and the film portion 70, for example.

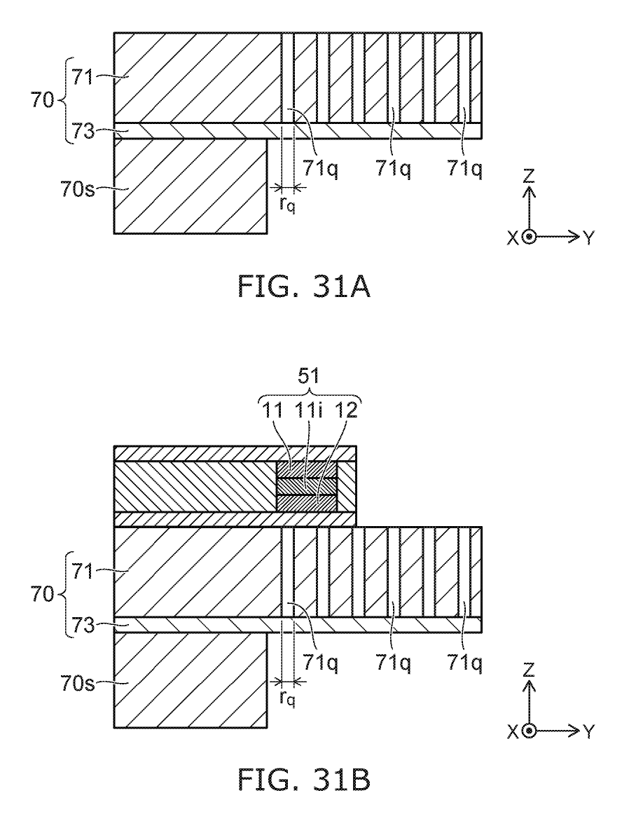

FIGS. 31A and 31B are schematic cross-sectional views illustrating a manufacturing method the sensor according to the embodiment.

As shown in FIG. 31A, the film potion 70 (in this example, the first film 71 and the third film 73) is formed.

As shown in FIG. 31B, the first sensor portion 51 is formed. For example, in the forming the first sensor portion 51, a heat treatment is performed. After this, the insulating film 75 (referring to FIG. 30) is formed.

In this example, at least a part of the gas etc. included in the film portion 70 is removed in the heat treatment. By forming the insulating film 75 after the heat treatment, the gas is removed effectively.

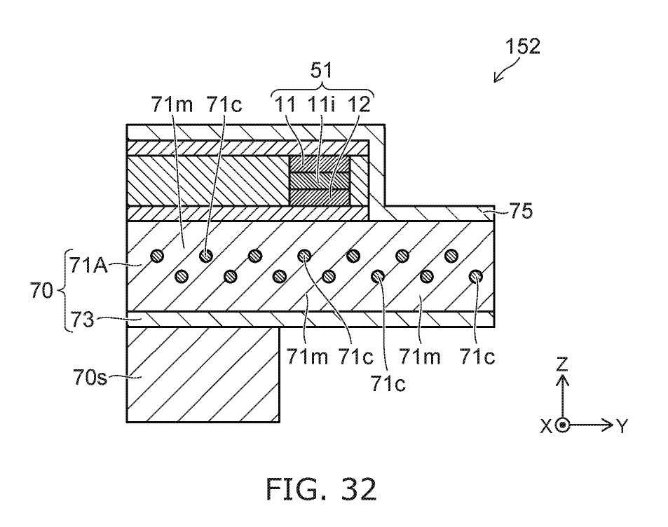

FIG. 32 is schematic cross-sectional views illustrating a portion of another sensor according to the embodiment.

FIG. 32 corresponds to the cross-sectional view shown in FIG. 1C. A sensor 152 includes the insulating film 75 in addition to the film portion 70 and the first sensor portion 51. The first sensor portion 51 is provided between a part of the insulating film 75 and the film portion 70. A part of the film portion 70 is located between a part of the insulating film 75 and the supporter 70s. The first film 71A is provided between another part of the insulating film 75 and the third film 73. The insulating film 75 protects the first sensor portion 51 and the film portion 70, for example.

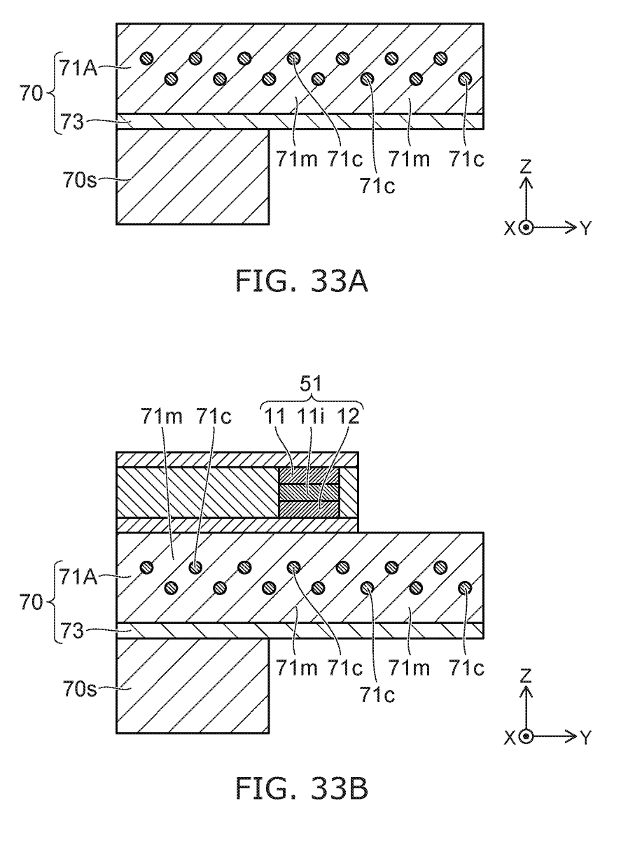

FIGS. 33A and 33B are schematic cross-sectional views illustrating a manufacturing method the sensor according to the embodiment.

As shown in FIG. 33A, the film potion 70 (in this example, the first film 71A and the third film 73) is formed.

As shown in FIG. 33B, the first sensor portion 51 is formed. For example, in the forming the first sensor portion 51, a heat treatment is performed. After this, the insulating film 75 (referring to FIG. 32) is formed.

In this example, at least a part of the gas etc. included in the film portion 70 is removed in the heat treatment. By forming the insulating film 75 after the heat treatment, the gas is removed effectively.

According to the embodiments, a sensor is provided in which the sensing precision can be increased.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, embodiments of the invention are described with reference to specific examples. However, the invention is not limited to these specific examples. For example, one skilled in the art may similarly practice the invention by appropriately selecting specific configurations of components included in the sensor such as the sensor portion, the magnetic layer, the film portion, etc., from known art; and such practice is within the scope of the invention to the extent that similar effects can be obtained.

Any two or more components of the specific examples may be combined within the extent of technical feasibility and are included in the scope of the invention to the extent that the purport of the invention is included.

Moreover, all sensors practicable by an appropriate design modification by one skilled in the art based on the sensors described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A sensor, comprising:
a film portion including a first film including a plurality of holes, the film portion being deformable; and
a first sensor portion fixed to a portion of the film portion, the first sensor portion including
a first magnetic layer,
a second magnetic layer provided between the first film and the first magnetic layer, and
a first intermediate layer provided between the first magnetic layer and the second magnetic layer,
a direction from at least a portion of the plurality of holes toward the first sensor portion being aligned with a first direction, the first direction being from the first film toward the first sensor portion.

2. The sensor according to claim 1, wherein
the film portion further includes a second film,
a direction from the first film toward the second film is aligned with the first direction, and
a density of the first film is lower than a density of the second film.

3. The sensor according to claim 1, wherein
the film portion further includes a second film,
a direction from the first film toward the second film is aligned with the first direction, and
the second film substantially does not include a hole.

4. The sensor according to claim 1, wherein
the film portion further includes a second film including a plurality of holes,
a direction from the first film toward the second film is aligned with the first direction, and
a density of the plurality of holes inside the first film is higher than a density of the plurality of holes inside the second film.

5. The sensor according to claim 1, wherein
the film portion further includes a second film,
a direction from the first film toward the second film is aligned with the first direction, and
a porosity of the first film is higher than a porosity of the second film.

6. The sensor according to claim 1, wherein
the film portion further includes a second film,
a direction from the first film toward the second film is aligned with the first direction, and
a surface roughness of a cross section of the first film is rougher than a surface roughness of a cross section of the second film.

7. The sensor according to claim 2, wherein a thickness along the first direction of the first film is thicker than a thickness along the first direction of the second film.

8. The sensor according to claim 2, wherein
the film portion further includes a third film,
a position in the first direction of the first film is between a position in the first direction of the second film and a position in the first direction of the third film, and
the density of the first film is lower than a density of the third film.

9. The sensor according to claim 2, wherein
the film portion further includes a third film,
a position in the first direction of the first film is between a position in the first direction of the second film and a position in the first direction of the third film, and
the third film substantially does not include a hole.

10. The sensor according to claim 4, wherein
the film portion further includes a third film including a plurality of holes,
a position in the first direction of the first film is between a position in the first direction of the second film and a position in the first direction of the third film, and
the density of the plurality of holes inside the first film is higher than a density of the plurality of holes inside the third film.

11. The sensor according to claim 5, wherein
the film portion further includes a third film,
a position in the first direction of the first film is between a position in the first direction of the second film and a position in the first direction of the third film, and
the porosity of the first film is higher than a porosity of the third film.

12. The sensor according to claim 6, wherein
the film portion further includes a third film,
a position in the first direction of the first film is between a position in the first direction of the second film and a position in the first direction of the third film, and
the surface roughness of the cross section of the first film is rougher than a surface roughness of a cross section of the third film.

13. The sensor according to claim 2, wherein the second film includes at least one selected from the group consisting of silicon, silicon oxide, aluminum oxide, silicon nitride, aluminum silicate, and silicon oxynitride.

14. The sensor according to claim 1, wherein the first film includes at least one selected from the group consisting of silicon oxide, aluminum oxide, titanium oxide, aluminum silicate, silicon oxynitride, and aluminophosphate.

15. The sensor according to claim 1, wherein a porosity of the first film is 30% or more.

16. A sensor, comprising:
a film portion including a first film including a metal compound portion and a carbon-including portion, the film portion being deformable; and
a first sensor portion fixed to a portion of the film portion, the first sensor portion including
a first magnetic layer,
a second magnetic layer provided between the first film and the first magnetic layer, and
a first intermediate layer provided between the first magnetic layer and the second magnetic layer,
a direction from at least a portion of the metal compound portion toward at least a portion of the carbon-including portion crossing a first direction from the first film toward the first sensor portion.

17. The sensor according to claim 16, wherein
the metal compound portion includes at least one selected from the group consisting of an oxide, a nitride, and an oxynitride,
the oxide includes at least one selected from the group consisting of silicon, aluminum, titanium, and tungsten,
the nitride includes at least one selected from the group consisting of silicon, aluminum, titanium, and tungsten, and
the oxynitride includes at least one selected from the group consisting of silicon, aluminum, titanium, and tungsten.

18. The sensor according to claim 16, wherein the carbon-including portion includes at least one selected from the group consisting of a hydroxy group, a carbonyl group, a carboxy group, an ether bond, an ester bond, an amine, and an imine.

19. The sensor according to claim 2, further comprising:
a first member having an opening; and
a second member,
the first sensor portion and the film portion being provided between the first member and the second member,
at least a portion of the second film being provided between the opening and at least a portion of the first film.
